(19) United States
(12) Patent Application Publication
(10) Pub. No.: US 2026/0304924 A1
(43) Pub. Date: Oct. 1, 2026

(54) SEMICONDUCTOR DEVICE INCLUDING ACTIVE PATTERN AND INSULATION STRUCTURE

(71) Applicant: Samsung Electronics Co., Ltd., Suwon-si (KR)

(72) Inventors: Daihong Huh, Suwon-si (KR); Sungyub Ji, Suwon-si (KR); Cheoljin Yun, Suwon-si (KR); Dahye Kim, Suwon-si (KR)

(73) Assignee: Samsung Electronics Co., Ltd., Suwon-si (KR)

(21) Appl. No.: 19/631,847

(22) Filed: Mar. 27, 2026

(30) Foreign Application Priority Data
Mar. 28, 2025 (KR) 10-2025-0040621

(51) Int. Cl. H10D 84/83; H10D 30/00; H10D 30/01; H10D 30/43; H10D 62/10; H10D 62/13; H10D 84/01

(52) U.S. Cl. CPC H10D 84/8311; H10D 30/43; H10D 30/502; H10D 62/121; H10D 62/151; H10D 84/83138; H10D 84/832; H10D 30/014; H10D 30/0191; H10D 84/0151

(57) ABSTRACT

A semiconductor device includes a first active pattern disposed above a substrate and including a plurality of first sheets disposed to be spaced apart from one another, a second active pattern disposed above the first active pattern and including a plurality of second sheets disposed to be spaced apart from one another, a first gate electrode configured to surround the first active pattern, a second gate electrode disposed above the first gate electrode, configured to surround the second active pattern, and an intermediate insulation structure overlapping the first active pattern and the second active pattern and disposed between the first gate electrode and the second gate electrode, and a step is formed on a side surface of the intermediate insulation structure.

### CROSS-REFERENCE TO RELATED APPLICATIONS

This present application claims priority to and the benefit under 35 U.S.C. § 119(a)-(d) of Korean Patent Application No. 10-2025-0040621, filed on Mar. 28, 2025, in the Korean Intellectual Property Office, the entire disclosure of which is incorporated herein by reference.

### FIELD

The present disclosure relates to a semiconductor device and more particularly to a semiconductor device including an active pattern and an insulation structure, and to a method of fabricating a semiconductor device.

### BACKGROUND

A multi-gate transistor in which a fin-shaped or nanowire-shaped silicon body is formed on a substrate and in which a gate is formed on a surface of the silicon body has been proposed as one of scaling technologies for increasing density of an integrated circuit device.

Meanwhile, as a scale of the multi-gate transistor is reduced, a three-dimensional stack semiconductor device in which a lower nano-sheet transistor and an upper nano-sheet transistor are stacked has been adopted.

### SUMMARY

According to aspects, there is provided a semiconductor device including a first active pattern disposed above a substrate and including a plurality of first sheets disposed to be spaced apart from one another along a first direction crossing a surface of the substrate, a second active pattern disposed above the first active pattern and including a plurality of second sheets disposed to be spaced apart from one another along the first direction, a first gate electrode configured to surround the first active pattern and extended along a second direction crossing the first direction, a second gate electrode disposed above the first gate electrode, configured to surround the second active pattern, and extended along the second direction, and an intermediate insulation structure overlapping the first active pattern and the second active pattern along the first direction and disposed between the first gate electrode and the second gate electrode in the first direction, and a step is formed on a side surface of the intermediate insulation structure in the second direction.

According to aspects, there is also provided a semiconductor device including a plurality of first active patterns disposed above a substrates, including a plurality of first sheets disposed to be spaced apart along a first direction crossing a surface of the substrate, and disposed to be spaced apart from one another along a second direction crossing the first direction, a plurality of second active patterns disposed above the plurality of first active patterns, including a plurality of second sheets disposed to be spaced apart along the first direction, and disposed to be spaced apart from one another along the second direction, a first gate electrode configured to surround the plurality of first active patterns and extended along the second direction, a second gate electrode disposed above the first gate electrode, configured to surround the plurality of second active patterns, and extended along the second direction, a gate separation structure disposed between the first gate electrode and the second gate electrode in the first direction and disposed between the plurality of first active patterns in the second direction, and an intermediate insulation structure disposed between an uppermost first sheet among the plurality of first sheets and a lowermost second sheet among the plurality of second sheets and disposed at a side of the gate separation structure in the second direction, and the intermediate insulation structure includes a first portion and a second portion that are connected to one another along the first direction, and a side surface of the first portion in the second direction is disposed, outwardly further than a side surface of the second portion in the second direction, toward the gate separation structure.

According to aspects, there is also provided a semiconductor device including a first active pattern disposed above a substrate and including a plurality of first sheets disposed to be spaced apart from one another along a first direction crossing a surface of the substrate, a second active pattern disposed above the first active pattern and including a plurality of second sheets disposed to be spaced apart from one another along the first direction, a first gate electrode configured to surround the first active pattern and extended along a second direction crossing the first direction, a second gate electrode disposed above the first gate electrode, configured to surround the second active pattern, and extended along the second direction, a first source/drain pattern disposed at a side of the first gate electrode in a third direction crossing the first direction and the second direction and connected to the first active pattern, a second source/drain pattern disposed at a side of the second gate electrode in the third direction crossing the first direction and the second direction and connected to the second active pattern, a first inter-layer insulation film disposed between the first source/drain pattern and the second source/drain pattern in the first direction, an intermediate insulation structure disposed between the first gate electrode and the second gate electrode in the first direction and disposed at a side of the first inter-layer insulation film in the third direction, and a gate separation structure disposed between the first gate electrode and the second gate electrode in the first direction, disposed at a side of the intermediate insulation structure in the second direction, and overlapping at least a portion of the first active pattern along the second direction, and the intermediate insulation structure includes a first portion disposed above the first gate electrode, and a second portion disposed on the first portion and of which a width along the second direction is smaller than that of the first portion along the second direction, and the gate separation structure is in contact with at least a portion of a side surface of the intermediate insulation structure.

### BRIEF DESCRIPTION OF THE DRAWINGS

These and/or other aspects, features, and advantages of the disclosure will become apparent and more readily appreciated from the following description of example embodiments, taken in conjunction with the accompanying drawings of which:

FIG. 1 is an example diagram illustrating a schematic layout of a semiconductor device according to some example embodiments;

FIG. 2 is an example diagram for describing a cross section taken along line A-A′ of FIG. 1;

FIG. 3 is an example diagram for describing a cross section taken along line B-B′ of FIG. 1;

FIG. 4 is an enlarged diagram illustrating section R1 of FIG. 3;

FIG. 5 is a diagram illustrating a cross section taken along line A-A′ of FIG. 1 for describing a semiconductor device according to example embodiments;

FIG. 6 is a diagram illustrating a cross section taken along line B-B′ of FIG. 1 for describing a semiconductor device according to example embodiments;

FIG. 7 is a diagram illustrating a cross section taken along line A-A′ of FIG. 1 for describing a semiconductor device according to example embodiments;

FIG. 8 is an enlarged diagram illustrating section R2 of FIG. 7;

FIG. 9 is a diagram illustrating a cross section taken along line B-B′ of FIG. 1 for describing a semiconductor device according to example embodiments;

FIG. 10 is a diagram illustrating a cross section taken along line B-B′ of FIG. 1 for describing a semiconductor device according to example embodiments;

FIGS. 11 through 35 are diagrams illustrating an intermediate operation for describing a method for fabricating a semiconductor device illustrated in FIGS. 2 and 3; and

FIGS. 36 through 42 are diagrams illustrating an intermediate operation for describing a method for fabricating a semiconductor package illustrated in FIG. 7.

### DETAILED DESCRIPTION

Before example embodiments are described, terms or words used in the present disclosure and the accompanying claims are not to be limited to general definitions or dictionary definitions. The terms and words are to be construed under a principle that an inventor may appropriately define a concept of a term in order to describe their disclosure in the best way. Thus, since example embodiments described in the present disclosure and configurations illustrated in the accompanying drawings are merely most desirable example embodiments and do not represent all of the technical spirit of the present disclosure, it should be understood that various equivalents and modifications that may replace the example embodiments and configurations may be present at the time of filing the application of the present disclosure.

In the following descriptions, terms in a singular form include terms in a plural form unless an apparently and contextually conflicting description is present. Terms such as “including” or “comprising” is to indicate that a feature, a number, an operation, an action, an element, a component, or a combination thereof is present. It should be understood that the terms are not to exclude in advance a possibility that one or more other features, numbers, operations, actions, elements, components, or combinations thereof may be present or added.

In the following descriptions, terms including an ordinal number such as “first” or “second” used in the present specification may be used to describe various elements. However, the elements may not be limited by the terms including the ordinal number. The terms may be used to contextually distinguish one element from another element in a part of the specification. Within a range of the technical spirit of the present disclosure, a first element may be referred to as a second element in another part of the specification, and reversely, the second element may be referred to as the first element in another part of the specification. Also, in the accompanying drawings, shapes, sizes, or the like of elements in the drawings may be exaggerated for clearer description.

In addition, it should be noted in advance that an expression such as an upper side, an upper portion, a lower side, a lower portion, a side surface, a front surface, or a rear surface is based on directions illustrated in the drawings and that the expression may be changed when a direction of a corresponding object is changed. Shapes, sizes, or the like of elements in the drawings may be exaggerated for clearer description.

Drawings for a semiconductor device according to some example embodiments illustrate a fin field-effect transistor (FinFET) including a channel area having a fin-shaped pattern shape, a transistor including a nanowire or a nanosheet, and a multi-bridge channel field effect transistor (MBCFET) as examples, but it is merely an example.

The semiconductor device according to some example embodiments may include a tunneling field-effect transistor (tunneling FET), a three-dimensional (3D) transistor, or a vertical field-effect transistor (vertical FET). The semiconductor device according to some example embodiments may also include a planar transistor. In addition, the technical idea of the present disclosure may be applied to two-dimensional material-based field-effect transistors (2D material based FETs) and a heterostructure thereof. Also, the semiconductor device according to some example embodiments may include a bipolar junction transistor, a lateral double-diffused transistor (e.g., laterally-diffused metal-oxide semiconductor (LDMOS)), or the like.

Hereinafter, the example embodiments of the present disclosure will be described with reference to the drawings.

Aspect provide a semiconductor device having an improved integration density.

Aspects also provide a semiconductor device having improved electrical reliability.

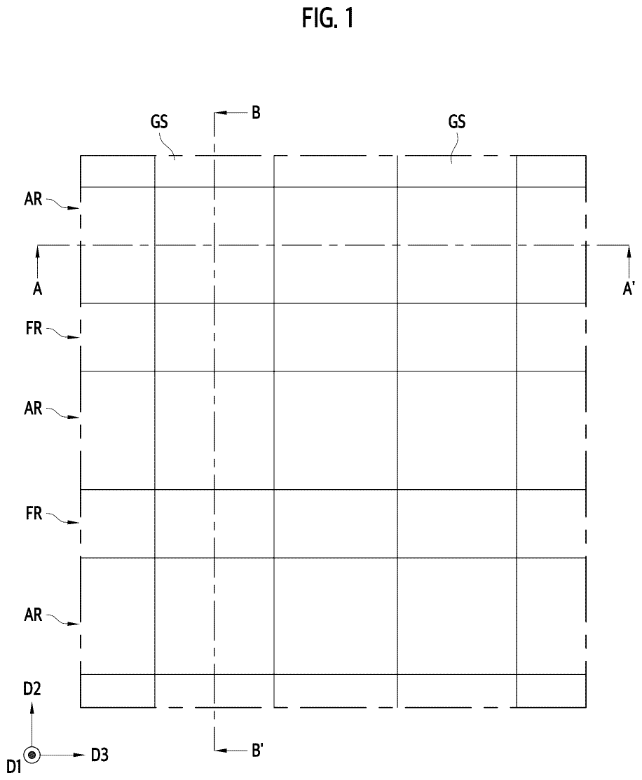

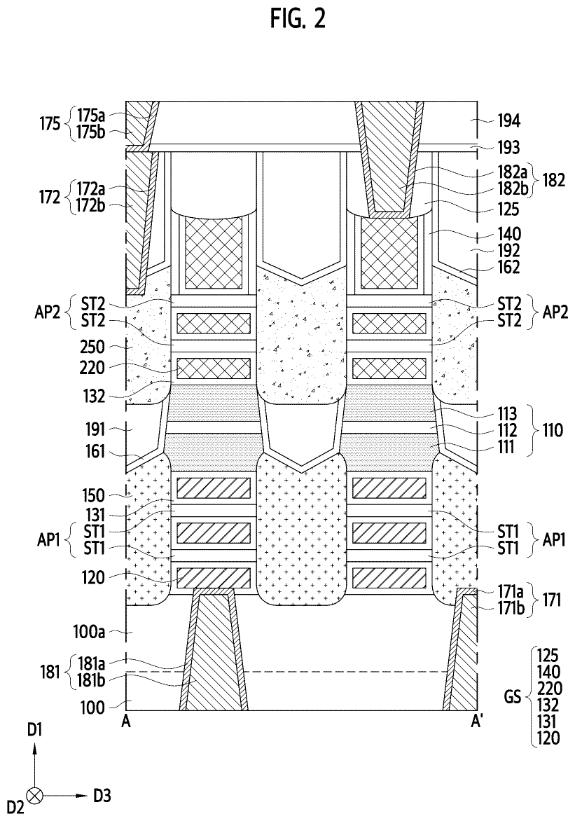

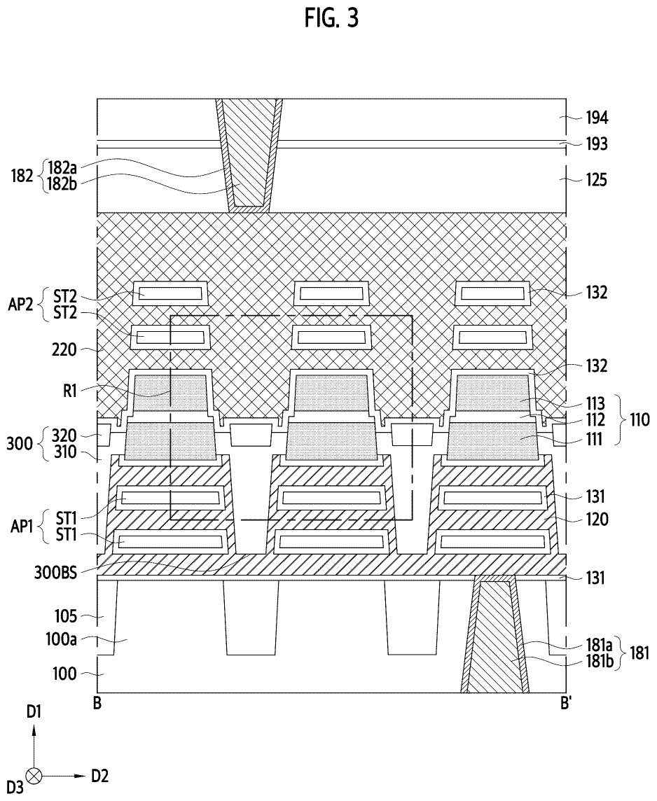

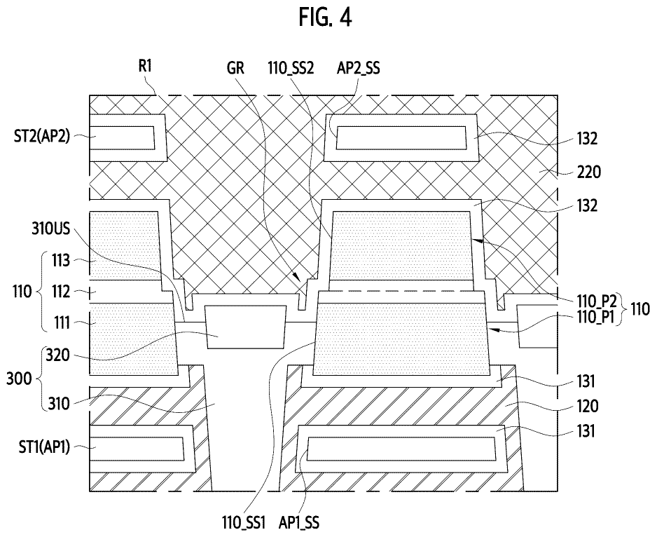

FIG. 1 is an example diagram illustrating a schematic layout of a semiconductor device according to some example embodiments. FIG. 2 is an example diagram for describing a cross section taken along line A-A′ of FIG. 1. FIG. 3 is an example diagram for describing a cross section taken along line B-B of FIG. 1. FIG. 4 is an enlarged diagram illustrating section R1 of FIG. 3.

Referring to FIGS. 1 through 4, the semiconductor device according to some example embodiments may include a first active pattern AP1, a second active pattern AP2, a first gate electrode 120, a second gate electrode 220, a first source/drain pattern 150, a second source/drain pattern 250, an intermediate insulation structure 110, and a gate separation structure 300.

According to some example embodiments, a substrate 100 may include an active region AR and a field region FR. The active region AR and the field region FR may be extended along a third direction D3. The active region AR and the field region FR may be alternately disposed along a second direction D2. For example, the active region AR may be disposed between field regions FR in the second direction D2. The field region FR may be disposed between active regions AR in the second direction D2. At this point, the second direction D2 and the third direction D3 each may refer to a direction parallel to the substrate 100 and crossing a first direction D1. The first direction D1 may refer to a direction crossing a surface of the substrate 100. For example, the first direction D1 may refer to a direction crossing an upper surface of the substrate 100. The second direction D2 may refer to a direction along which the active region AR and the field region FR are alternately disposed. The third direction D3 may refer to a direction along which the active region AR and the field region FR are extended.

According to some example embodiments, the field region FR may be defined by a trench, but it is merely an example. In addition, it is apparent that those skilled in the art to which the present disclosure belongs may distinguish what portion a field region is and what portion an active region is. The field region FR may have a shallow trench isolation (STI) structure. However, it is merely an example. For example, the field region FR may be defined by a deep trench.

According to some example embodiments, an element separator may be disposed near the active regions AR which are spaced apart from one another. At this point, a portion of the element separator, which is between two adjacent active regions AR, may be the field area FR. For example, a portion at which a channel region of a transistor which may be an example of the semiconductor device is formed may be the active region, or a portion separating the channel region of the transistor, which is formed in the active region, may be the field region. Alternatively, the active region may be a portion at which a fin-shaped pattern or a nanosheet used as the channel region of the transistor is formed, and the field region may be a region in which the fin-shaped pattern or the nanosheet used as the channel region is not formed.

According to some example embodiments, the substrate 100 may be bulk silicon or silicon-on-insulator (SOI). In contrast, the substrate 100 may be a silicon substrate or include another material such as silicon germanium, silicon germanium on insulator (SGOI), indium antimonide, lead telluride, indium arsenide, indium phosphide, gallium arsenide, or gallium antimonide, but it is merely an example.

According to some example embodiments, the substrate 100 may include an insulation material. For example, the substrate 100 may include at least one of silicon oxide (SiO₂), silicon nitride (SiN), silicon oxynitride (SiON), silicon oxycarbide (SiOC), silicon carbonitride (SiCN), and siliscon oxycarbonitride (SiOCN).

FIGS. 2 and 3 illustrate that the substrate 100 is disposed below a fin-shaped pattern 100a, but it is merely an example. As an example, the substrate 100 may not be disposed below the fin-shaped pattern 100a. The substrate 100 which is disposed below the fin-shaped pattern 100a may be removed in a process of fabricating the semiconductor device according to some example embodiments. As another example, the fin-shaped pattern 100a and the substrate 100 may not be disposed below the first gate electrode 120 and the first source/drain pattern 150. As another example, the fin-shaped pattern 100a and the substrate 100 which are disposed below the first gate electrode 120 and the first source/drain pattern 150 may be removed, and an inter-layer insulation film may be formed.

According to some example embodiments, the fin-shaped pattern 100a may be disposed on the active region AR of the substrate 100. The fin-shaped pattern 100a may protrude from the substrate 100. The fin-shaped pattern 100a may be extended along the third direction D3. The fin-shaped pattern 100a may be formed by etching a portion of the substrate 100 or may include an epitaxial layer grown from the substrate 100. The fin-shaped pattern 100a may include silicon or germanium that is an elemental semiconductor material.

According to some example embodiments, the fin-shaped pattern 100a may include silicon (Si). As another example, the fin-shaped pattern 100a may include a compound semiconductor and may include, for example, a group IV-IV compound semiconductor or a group III-V compound semiconductor. The group IV-IV compound semiconductor may be a binary compound or a ternary compound including at least two of carbon (C), silicon (Si), germanium (Ge), and tin (Sn) or may be a compound obtained by doping the above-described compounds with a group IV element. The group III-V compound semiconductor may be, for example, one of a binary compound, a ternary compound, or a quaternary compound formed in combination of at least one of aluminum (Al), gallium (Ga), and indium (In) of group III elements and one of phosphorus (P), arsenic (As), and antimony (Sb) of group V elements. For example, the fin-shaped pattern 100a may include a semiconductor material. The fin-shaped pattern 100a may include at least one of silicon, germanium, the group IV-IV compound semiconductor, and the group III-V compound semiconductor.

According to some example embodiments, the fin-shaped pattern 100a may include an insulation material. For example, the fin-shaped pattern 100a may include at least one of silicon oxide (SiO₂), silicon nitride (SiN), silicon oxynitride (SiON), silicon carbonitride (SiCN), silicon oxycarbide (SiOC), and silicon oxycarbonitride (SiOCN).

According to some example embodiments, the first active pattern AP1 may be disposed above the active region AR of the substrate 100. The first active pattern AP1 may be disposed above the fin-shaped pattern 100a. For example, the first active pattern AP1 may be an active pattern including a nanosheet or a nanowire. The first active pattern AP1 may include a plurality of first sheets ST1. The plurality of first sheets ST1 may be disposed above the substrate 100. The plurality of first sheets ST1 may be disposed to be spaced apart from the substrate 100 along the first direction D1. The plurality of first sheets ST1 may be disposed to be spaced apart from one another along the first direction D1. The plurality of first sheets ST1 may be extended along the third direction D3.

According to some example embodiments, a plurality of first active patterns AP1 may be disposed. The plurality of first active patterns AP1 may be disposed to be spaced apart along the second direction D2. For example, the first active pattern AP1 may be disposed in each of two active regions AR spaced apart along the second direction D2.

According to some example embodiments, along the third direction D3, the first active pattern AP1 may be disposed between first source/drain patterns 150. The first active pattern AP1 may be connected to the first source/drain pattern 150.

According to some example embodiments, the second active pattern AP2 may be disposed above the active region AR of the substrate 100. The second active pattern AP2 may be disposed above the first active pattern AP1. The second active pattern AP2 may be spaced apart from the first active pattern AP1 along the first direction D1. For example, the second active pattern AP2 may be an active pattern including a nanosheet or a nanowire. The second active pattern AP2 may include a plurality of second sheets ST2. The plurality of second sheets ST2 may be disposed above the plurality of first sheets ST1. The plurality of second sheets ST2 may be disposed to be spaced apart from one another along the first direction D1. The plurality of second sheets ST2 may be extended along the third direction D3.

According to some example embodiments, a plurality of second active patterns AP2 may be disposed. The plurality of second active patterns AP2 may be disposed to be spaced apart along the second direction D2. For example, the second active pattern AP2 may be disposed in each of two active regions AR spaced apart along the second direction D2.

According to some example embodiments, along the third direction D3, the second active pattern AP2 may be disposed between second source/drain patterns 250. The second active pattern AP2 may be connected to the second source/drain pattern 250.

For example, widths of the plurality of first sheets ST1 of the first active pattern AP1 and the plurality of second sheets ST2 of the second active pattern AP2, each of which is along the direction D2, may become larger or smaller in proportion to a width, along the second direction D2, of the fin-shaped pattern 100a disposed below the first active pattern AP1. A width of the second active pattern AP2 along the second direction D2 may be smaller than a width of the first active pattern AP1 along the second direction D2.

According to some example embodiments, the first active pattern AP1 and the second active pattern AP2 may include, for example, silicon or germanium that is an elemental semiconductor material. In addition, the first active pattern AP1 and the second active pattern AP2 may include a compound semiconductor, for example, may include a group IV-IV compound semiconductor or a group III-V compound semiconductor.

The group IV-IV compound semiconductor may be a binary compound or a ternary compound including at least two or more of carbon (C), silicon (Si), germanium (Ge), and tin (Sn) or may be a compound obtained by doping the above-described compounds with a group IV element.

The group III-V compound semiconductor may be, for example, one of a binary compound, a ternary compound, or a quaternary compound formed in combination of at least one of aluminum (Al), gallium (Ga), and indium (In) of group III elements and one of phosphorus (P), arsenic (As), and antimony (Sb) of group V elements.

According to some example embodiments, the first active pattern AP1 and the second active pattern AP2 each may include a material identical to that of the fin-shaped pattern 100a or may include a material different from that of the fin-shaped pattern 100a. The fin-shaped pattern 100a is a silicon fin-shaped pattern that includes silicon, and the first active pattern AP1 and the second active pattern AP2 may be a silicon sheet pattern that includes silicon. The first active pattern AP1 and the second active pattern AP2 each may not include a P-type impurity or an N-type impurity. The first active pattern AP1 and the second active pattern AP2 may include silicon alone.

FIGS. 2 and 3 illustrates that the first active pattern AP1 and the second active pattern AP2 includes two first sheets ST1 and two second sheets ST2, respectively, but it is merely an example. For example, the first active pattern AP1 and the second active pattern AP2 each may include three or more sheets.

According to some example embodiments, a field insulation film 105 may be disposed in the field region FR. The field insulation film 105 may be disposed above the substrate 100. For example, the field insulation film 105 may be disposed between fin-shaped patterns 100a spaced apart along the second direction D2. The field insulation film 105 may be disposed above the substrate 100 which does not overlap the first active pattern AP1 and the second active pattern AP2 along the first direction D1. The field insulation film 105 may fill at least a portion of a trench formed on the substrate 100.

According to some example embodiments, the field insulation film 105 may cover a side surface of the fin-shaped pattern 100a. An upper surface of the field insulation film 105 and an upper surface of the fin-shaped pattern 100a may be disposed on an identical plane. Unlike an illustration, as another example, the field insulation film 105 may cover a portion of the side surface of the fin-shaped pattern 100 alone. In such a case, a portion of the fin-shaped pattern 100 may protrude along the first direction D1 further than the field insulation film 105. For example, the field insulation film 105 may include an oxide film, a nitride film, an oxynitride film, or a film in combination thereof. The field insulation film 105 is illustrated as a single film, but it is merely for convenience for description, and it is merely an example.

According to some example embodiments, a gate structure GS may be disposed above the substrate 100. Each gate structure GS may be extended along the second direction D2. Gate structures GS may be disposed to be spaced apart along the third direction D3. The gate structures GS may be adjacent to one another along the third direction D3.

According to some example embodiments, the gate structure GS may be disposed above the first active pattern AP1 and the second active pattern AP2. For example, the gate structure GS may cross the first active area AP1 and the second active area AP2.

According to some example embodiments, the gate structure GS may surround the first active pattern AP1 and the second active pattern AP2. Specifically, the first gate electrode 120 and the second gate electrode 220 of the gate structure GS may surround the plurality of first sheets ST1 and the plurality of second sheets ST2 respectively.

FIG. 3 illustrates that the first gate electrode 120 and the second gate electrode 220 are disposed across the active region AR and the field region FR, but it is merely an example. For example, the gate structure GS may not be continuously extended along the second direction D2 across two active regions AR, which are spaced apart along the second direction D2 with the field region FR in between, and may be separated at the field region FR. In such a case, a gate structure GS that is extended along the second direction D2 and crosses one active region AR and another gate structure GS that is extended along the second direction D2 and crosses another active region AR may be spaced apart from one another along the second direction D2.

According to some example embodiments, the gate structure GS may include the first gate electrode 120, the second gate electrode 220, a first gate insulation film 131, a second gate insulation film 132, a gate spacer 140, and a gate capping film 125.

According to some example embodiments, the first gate electrode 120 and the second gate electrode 220 may be extended along the second direction D2. The first gate electrode 120 may be disposed between the first source/drain patterns 150 which are adjacent to one another along the third direction D3. The second gate electrode 220 may be disposed between the second source/drain patterns 250 which are adjacent to one another along the third direction D3.

According to some example embodiments, the first gate electrode 120 and the second gate electrode 220 may be formed above the fin-shaped pattern 100a. According to some example embodiments, the first gate electrode 120 and the second gate electrode 220 may cross the fin-shaped pattern 100a.

According to some example embodiments, the first gate electrode 120 may surround the first active pattern AP1. The first gate electrode 120 may be penetrated by the first active pattern AP1. A portion of the first gate electrode 120 may be disposed between first sheets ST1 adjacent to one another along the first direction D1. A portion of the first gate electrode 120 may be disposed between the intermediate insulation structure 110 and an uppermost first sheet ST1 disposed to be highest among the plurality of first sheets ST1. The first gate electrode 120 may surround at least a portion of a first separator 310 of the gate separation structure 300. The first gate electrode 120 may be in contact with the first separator 310.

According to some example embodiments, the second gate electrode 220 may surround the second active pattern AP2. The second gate electrode 220 may be penetrated by the second active pattern AP2. A portion of the second gate electrode 220 may be disposed between second sheets ST2 adjacent to one another along the first direction D1. A portion of the second gate electrode 220 may be disposed between the intermediate insulation structure 110 and a lowermost second sheet ST2 disposed to be lowest among the plurality of second sheets ST2. The second gate electrode 220 may surround a portion of a second separator 320 protruding above an upper surface 310US of the first separator 310. The second gate electrode 220 may not be in contact with the second separator 320 and may be spaced apart therefrom with the second gate insulation film 132 in between.

According to some example embodiments, the first gate electrode 120 and the second gate electrode 220 each may include at least one of a metal, a metal alloy, a conductive metallic nitride, a metallic silicide, a doped semiconductor material, a conductive metallic oxide, and a conductive metallic oxynitride. Gate electrodes 120 and 220 may include, for example, at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAlN), tantalum aluminum nitride (TaAlN), tungsten nitride (WN), ruthenium (Ru), titanium aluminum (TiAl), titanium aluminum carbonitride (TiAlC—N), titanium aluminum carbide (TiAlC), titanium carbide (TiC), tantalum carbonitride (TaCN), tungsten (W), aluminum (Al), copper (Cu), cobalt (Co), titanium (Ti), tantalum (Ta), nickel (Ni), platinum (Pt), nickel platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), and a combination thereof, but it is merely an example. The conductive metallic oxide and the conductive metallic oxynitride may include a form in which the above-described substance is oxidized, but it is merely an example.

According to some example embodiments, the first gate electrode 120 may be disposed at both sides of the first source/drain pattern 150 in the third direction D3. The second gate electrode 220 may be disposed at both sides of the second source/drain pattern 250 in the third direction D3. The gate structure GS may be disposed at the both sides of the first source/drain pattern 150 and the both sides of the second source/drain pattern 250, which are in the third direction D3.

As an example, all first gate electrodes 120 that are disposed at the both sides of the first source/drain pattern 150 may be a normal gate electrode used as a gate of the transistor. As another example, the first gate electrode 120 which is disposed at a side of the first source/drain pattern 150 may be used as the gate of the transistor, but the first gate electrode 120 which is disposed at another side of the first source/drain pattern 150 may be a dummy gate electrode.

As an example, all second gate electrodes 220 that are disposed at the both sides of the second source/drain pattern 250 may be a normal gate electrode used as the gate of the transistor. As another example, the second gate electrode 220 which is disposed at a side of the second source/drain pattern 250 may be used as the gate of the transistor, but the second gate electrode 220 which is disposed at another side of the second source/drain pattern 250 may be a dummy gate electrode.

According to some example embodiments, the first gate insulation film 131 may be extended along the upper surface of the field insulation film 105 and the upper surface of the fin-shaped pattern 100a. The first gate insulation film 131 may surround the first active pattern AP1. The first gate insulation film 131 may surround the first gate electrode 120. The first gate insulation film 131 may be disposed around the plurality of first sheets ST1. The first gate insulation film 131 may be disposed between the first gate electrode 120 and the first active pattern AP1. The first gate insulation film 131 may cover a lower surface of the intermediate insulation structure 110. For example, the first gate insulation film 131 may cover a lower surface of a first portion 110_P1 of the intermediate insulation structure 110.

According to some example embodiments, the second gate insulation film 132 may be extended along upper surfaces of the intermediate insulation structure 110 and the gate separation structure 300. According to some example embodiments, the second gate insulation film 132 may be extended along surficial profiles of the intermediate insulation structure 110 and the gate separation structure 300 above the first gate electrode 120. The second gate insulation film 132 may surround the second active pattern AP2. The second gate insulation film 132 may surround the second gate electrode 220. The second gate insulation film 132 may be disposed around the plurality of second sheets ST2. The second gate insulation film 132 may be disposed between the second gate electrode 220 and the second active pattern AP2. The second gate insulation film 132 may cover an upper surface of the intermediate insulation structure 110. For example, the second gate insulation film 132 may cover an upper surface of a second portion 110_P2 of the intermediate insulation structure 110.

According to some example embodiments, the first gate electrode 131 and the second gate electrode 132 may not be connected to one another. The first gate insulation film 131 and the second gate insulation film 132 may be spaced apart with the gate separation structure 300 and the intermediate insulation structure 110 in between.

According to some example embodiments, the first gate insulation film 131 and the second gate insulation film 132 may include silicon oxide, silicon-germanium oxide, germanium oxide, silicon oxynitride, silicon nitride, or a high-permittivity material having a dielectric constant higher than that of silicon oxide. The high-permittivity material may include, for example, one or more of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate.

FIGS. 2 through 4 illustrate that the first gate insulation film 131 and the second gate insulation film 132 each are a single film, but it is merely for convenience for description, and it is merely an example. The first gate insulation film 131 and the second gate insulation film 132 each may include a plurality of films. The first gate insulation film 131 and the second gate insulation film 132 each may include an interfacial layer disposed between the first active pattern AP1 and the first gate electrode 120 or between the second active pattern AP2 and the second gate electrode 220 and include a high-permittivity insulation film.

The semiconductor device according to some example embodiments may include a negative capacitance (NC) field effect transistor (FET) that uses a negative capacitor. For example, a gate insulation film 130 may include a ferroelectric material film having a ferroelectric characteristic and a paraelectric material film having a paraelectric characteristic.

According to some example embodiments, the ferroelectric material film may have negative capacitance, and the paraelectric material film may have positive capacitance. For example, when two or more capacitors are connected in series, and when capacitance of each of the capacitors has a positive value, total capacitance is decreased below capacitance of each individual capacitor. In contrast, when at least one of the two or more capacitors connected in series has a negative capacitance value, the total capacitance may be larger than an absolute value of capacitance of each individual capacitor while having a positive value.

According to some example embodiments, when the ferroelectric material film having the negative capacitance and the paraelectric material film having the positive capacitance are connected in series, a total capacitance value of the ferroelectric material film and the paraelectric material film connected in series may be increased. A transistor having the ferroelectric material film may have a subthreshold swing (SS) less than 60 millivolts (mV)/decade at normal temperature by using an increase in the total capacitance value.

According to some example embodiments, the ferroelectric material film may have the ferroelectric characteristic. The ferroelectric material film may include, for example, at least one of hafnium oxide, hafnium zirconium oxide, barium strontium titanium oxide, barium titanium oxide, and lead zirconium titanium oxide. Here, as an example, hafnium zirconium oxide is a material obtained by doping hafnium oxide with zirconium (Zr). As another example, hafnium zirconium oxide may be a compound of hafnium (Hf), zirconium (Zr), and oxygen (O).

According to some example embodiments, the ferroelectric material film may further include a doped dopant. For example, the dopant may include at least one of aluminum (Al), titanium (Ti), niobium (Nb), lanthanum (La), yttrium (Y), magnesium (Mg), silicon (Si), calcium (Ca), cerium (Ce), dysprosium (Dy), erbium (Er), gadolinium (Gd), germanium (Ge), scandium (Sc), strontium (Sr), and tin (Sn). A type of the dopant included in the ferroelectric material film may vary depending on what ferroelectric material the ferroelectric material film includes.

According to some example embodiments, when the ferroelectric material film includes hafnium oxide, the dopant included in the ferroelectric material film may include, for example, at least one of gadolinium (Gd), silicon (Si), zirconium (Zr), aluminum (Al), and yttrium (Y).

According to some example embodiments, when the dopant is aluminum (Al), the ferroelectric material film may include 3 to 8 at % (atomic percent) of aluminum. Here, a ratio of the dopant may be a ratio of the aluminum to a sum of hafnium and the aluminum.

According to some example embodiments, when the dopant is silicon (Si), the ferroelectric material film may include 2 to 10 at % of silicon. When the dopant is yttrium (Y), the ferroelectric material film may include 2 to 10 at % of yttrium. When the dopant is gadolinium (Gd), the ferroelectric material film may include 1 to 7 at % of gadolinium. When the dopant is zirconium (Zr), the ferroelectric material film may include 50 to 80 at % of zirconium.

According to some example embodiments, the paraelectric material film may have the paraelectric characteristic. The paraelectric material film may include, for example, at least one of silicon oxide and a metallic oxide having high-permittivity. The metallic oxide included in the paraelectric material film may include, for example, at least one of hafnium oxide, zirconium oxide, and aluminum oxide, but it is merely an example.

According to some example embodiments, the ferroelectric material film and the paraelectric material film may include an identical material. The ferroelectric material film may have the ferroelectric characteristic, but the paraelectric material film may not have the ferroelectric characteristic. For example, when the ferroelectric material film and the paraelectric material film include hafnium oxide, a crystal structure of the hafnium oxide which is included in the ferroelectric material film may be different from a crystal structure of the hafnium oxide which is included in the paraelectric material film.

According to some example embodiments, the ferroelectric material film may have a thickness showing the ferroelectric characteristic. The thickness of the ferroelectric material film may be, for example, 0.5 to 10 nanometers (nm), but it is merely an example. Since respective threshold thicknesses of ferroelectric materials, which show the ferroelectric characteristic, may be different, the thickness of the ferroelectric material film may vary depending on a ferroelectric material.

As an example, the gate insulation film 130 may include one ferroelectric material film. As another example, the gate insulation film 130 may include a plurality of ferroelectric material films spaced apart from one another. The gate insulation film 130 may have a stacked film structure in which the plurality of ferroelectric material films and a plurality of paraelectric material films are alternately stacked.

According to some example embodiments, the gate spacer 140 may be disposed on a side surface of the second gate electrode 220. The gate spacer 140 may not be disposed between the fin-shaped pattern 100a and a first sheet ST1, between the plurality of first sheets ST1 adjacent along the first direction D1, between the plurality of second sheets ST2 adjacent along the first direction D1, and between a second sheet ST2 and the intermediate insulation structure 110. However, it is merely an example. For example, the gate spacer 140 may be disposed between the fin-shaped pattern 100a and a first sheet ST1, between the plurality of first sheets ST1 adjacent along the first direction D1, between the plurality of second sheets ST2 adjacent along the first direction D1, and between a second sheet ST2 and the intermediate insulation structure 110.

FIG. 2 illustrates that the gate spacer 140 is disposed exclusively on the side surface of the second gate electrode 220, but it is merely an example. For example, the gate spacer 140 may be also disposed on a side surface of the first gate electrode 120.

According to some example embodiments, the gate spacer 140 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and a combination thereof. The gate spacer 140 is illustrated as a single film, but it is merely for convenience for description, and it is merely an example.

According to some example embodiments, the gate capping film 125 may be disposed on the second gate electrode 220 and the gate spacer 140. An upper surface of the gate capping film 125 and an upper surface of a second inter-layer insulation film 192 may be disposed on an identical plane. Unlike an illustration, the gate capping film 125 may be disposed between gate spacers 140. In such a case, the upper surface of the gate capping film 125, an upper surface of the gate spacer 140, and an upper surface of the second inter-layer insulation film 192 may be disposed on an identical plane.

According to some example embodiments, the gate capping film 125 may include, for example, at least one of silicon nitride (SiN), silicon oxide (SiO₂), silicon oxynitride (SiON), silicon carbonitride (SiCN), silicon oxycarbonitride (SiOCN), and a combination thereof. The gate capping film 125 may include a material having an etch selectivity for the second inter-layer insulation film 192.

According to some example embodiments, the first source/drain pattern 150 and the second source/drain pattern 250 may be disposed in the active region AR1. The first source/drain pattern 150 and the second source/drain pattern 250 may be disposed along the first direction D1. For example, the first source/drain pattern 150 may be disposed closer to the substrate 100 than the second source/drain pattern 250 in the first direction D1. The second source/drain pattern 250 may be disposed above the first source/drain pattern 150 along the first direction D1.

According to some example embodiments, the first source/drain pattern 150 and the second source/drain pattern 250 may have different conductivity types. The first source/drain pattern 150 may have P-type conductivity, and the second source/drain pattern 250 may have N-type conductivity. The first source/drain pattern 150 may include a P-type dopant. The P-type dopant may include at least one of boron (B) and gallium (Ga), but it is merely an example. The second source/drain pattern 250 may include an N-type dopant. The N-type dopant may include at least one of phosphorus (P), arsenic (As), antimony (Sb), and bismuth (Bi), but it is merely an example. As another example, the first source/drain pattern 150 may have the N-type conductivity, and the second source/drain pattern 250 may have the P-type conductivity.

According to some example embodiments, the first source/drain pattern 150 may be connected to the first active pattern AP1. The first source/drain pattern 150 may be disposed between first active patterns AP1 in the third direction D3. The first source/drain pattern 150 may be connected to the first active pattern AP1 along the third direction D3. The first source/drain pattern 150 may be disposed between first gate electrodes 120 that are adjacent to one another along the third direction D3. The first source/drain pattern 150 may be disposed on the fin-shaped pattern 100a.

According to some example embodiments, the first source/drain pattern 150 may be a source/drain of a p-channel metal-oxide-semiconductor (PMOS) transistor. The first source/drain pattern 150 may be a source/drain of a transistor that uses the first active pattern AP1 as a channel region.

According to some example embodiments, the second source/drain pattern 250 may be connected to the second active pattern AP2. The second source/drain pattern 250 may be disposed between second active patterns AP2 in the third direction D3. The second source/drain pattern 250 may be connected to the second active pattern AP2 in the third direction D3. The second source/drain pattern 250 may be disposed between the second gate electrodes 220 which are adjacent to one another along the third direction D3. The second source/drain pattern 250 may be disposed on a first inter-layer insulation film 191. The second source/drain pattern 250 may be spaced apart from the first source/drain pattern 150 along the first direction D1.

According to some example embodiments, the second source/drain pattern 250 may be a source/drain of an n-channel metal-oxide-semiconductor (NMOS) transistor. The second source/drain pattern 250 may be a source/drain of a transistor that uses the second active pattern AP2 as a channel region.

According to some example embodiments, a first source/drain etch stop film 161 and the first inter-layer insulation film 191 may be disposed above the first source/drain pattern 150. The first source/drain etch stop film 161 may be extended along an upper surface of the first source/drain pattern 150 and the upper surface of the field insulation film 105. In addition, the first source/drain etch stop film 161 may be extended along the intermediate insulation structure 110 which is disposed between the first sheet ST1 and the second sheet ST2 which are adjacent along the first direction D1.

According to some example embodiments, the first source/drain etch stop film 161 may include at least one of silicon nitride (SiN), silicon oxide (SiO₂), silicon oxynitride (SiON), silicon oxycarbonitride (SiOCN), silicon boronitride (SiBN), silicon oxyboronitride (SiOBN), silicon oxycarbide (SiOC), and a combination thereof.

According to some example embodiments, the first inter-layer insulation film 191 may be disposed on the first source/drain etch stop film 161. The first inter-layer insulation film 191 may be formed above the field insulation film 105. Along the first direction D1, the first inter-layer insulation film 191 may be disposed between the first source/drain pattern 150 and the second source/drain pattern 250. The first inter-layer insulation film 191 may cover a lower surface of the second source/drain pattern 250.

According to some example embodiments, the first inter-layer insulation film 191 may include, for example, at least one of silicon oxide, silicon nitride, silicon oxynitride, and a low-permittivity material. The low-permittivity material may include, for example, fluorinated tetraethylorthosilicate (FTEOS), hydrogen silsesquioxane (HSQ), bis-benzocyclobutene (BCB), tetramethylorthosilicate (TMOS), octamethyleyclotetrasiloxane (OMCTS), hexamethyldisiloxane (HMDS), trimethylsilyl borate (TMSB), diacetoxyditertiarybutosiloxane (DADBS), trimethylsilil phosphate (TMSP), polytetrafluoroethylene (PTFE), Tonen SilaZen (TOSZ), fluoride silicate glass (FSG), polyimide nanofoams such as polypropylene oxide, carbon doped silicon oxide (CDO), organo silicate glass (OSG), SiLK, amorphous fluorinated carbon, silica aerogels, silica xerogels, mesoporous silica, or a combination thereof, but it is merely an example.

According to some example embodiments, a second source/drain etch stop film 162 and the second inter-layer insulation film 192 may be disposed above the second source/drain pattern 250. The second source/drain etch stop film 162 may be extended along an upper surface of the second source/drain pattern 250, a side surface of the second source/drain pattern 250, and an upper surface of the first inter-layer insulation film 191. The second inter-layer insulation film 192 may not cover an upper surface of the gate structure GS. For example, the upper surface of the second inter-layer insulation film 192 and the upper surface of the gate structure GS may be disposed on an identical plane.

In addition to the above description, since being substantially identical to descriptions of the first source/drain etch stop film 161 and the first inter-layer insulation film 191, descriptions of the second source/drain etch stop film 162 and the second inter-layer insulation film 192 will be omitted.

According to some example embodiments, the intermediate insulation structure 110 may be disposed between the first gate electrode 120 and the second gate electrode 220 in the first direction D1. The intermediate insulation structure 110 may overlap the first active pattern AP1 and the second active pattern AP2 along the first direction D1. According to some example embodiments, the intermediate insulation structure 110 may be disposed between the first active pattern AP1 and the second active pattern AP2 in the first direction D1. The intermediate insulation structure 110 may be disposed between the uppermost first sheet ST1 and the lowermost second sheet ST2 in the first direction D1. The intermediate insulation structure 110 may be disposed between gate separation structures 300 in the second direction D2. The intermediate insulation structure 110 may be disposed at a side of the gate separation structure 300 in the second direction D2. According to some example embodiments, the intermediate insulation structure 110 may be disposed between first source/drain etch stop films 161 and between first inter-layer insulation films 191 in the third direction D3.

According to some example embodiments, the intermediate insulation structure 110 may include the first portion 110_P1 and the second portion 110_P2. The first portion 110_P1 and the second portion 110_P2 may be disposed along the first direction D1. The first portion 110_P1 and the second portion 110_P2 may be connected to one another along the first direction D1. The first portion 110_P1 may be disposed above the first gate electrode 120. The second portion 110_P2 may be disposed on the first portion 110_P1.

According to some example embodiments, a width of the first portion 110_P1 along the second direction D2 and a width of the second portion 110_P2 along the second direction D2 may differ. The width of the first portion 110_P1 along the second direction D2 may be larger than the width of the second portion 110_P2 along the second direction D2.

According to some example embodiments, the intermediate insulation structure 110 may have a step on a side surface in the second direction D2. The step may be formed on the side surface of the intermediate insulation structure 110 in the second direction D2. The first portion 110_P1 and the second portion 110_P2 which have different widths along the second direction D2 may be connected while forming the step. For example, the step may be formed between a side surface 110_SS1 of the first portion 110_P1 and a side surface 110_SS2 of the second portion 110_P2.

According to some example embodiments, the side surface 110_SS1 of the first portion 110_P1 and the side surface 110_SS2 of the second portion 110_P2 may not be aligned with one another. The side surface 110_SS1 of the first portion 110_P1 and the side surface 110_SS2 of the second portion 110_P2 not being aligned with one another may mean that the side surface 110_SS1 of the first portion 110_P1 and the side surface 110_SS2 of the second portion 110_P2 are not disposed on an identical plane. The side surface 110_SS1 of the first portion 110_P1 in the second direction D2 may be disposed, outwardly further than the side surface 110_SS2 of the second portion 110_P2, toward the gate separation structure 300. For example, along the second direction D2, a distance between the side surface 110_SS1 of the first portion 110_P1 and the gate separation structure 300 may be smaller than a distance between the side surface 110_SS2 of the second portion 110_P2 and the gate separation structure 300.

According to some example embodiments, the side surface 110_SS1 of the first portion 110_P1 in the second direction D2 may be aligned with a side surface AP1_SS of the first active pattern AP1. The side surface 110_SS1 of the first portion 110_P1 in the second direction D2 being aligned with the side surface AP1_SS of the first active pattern AP1 may mean that the side surface 110_SS1 of the first portion 110_P1 in the second direction D2 and the side surface AP1_SS of the first active pattern AP1 are disposed on an identical plane. This may be due to the first portion 110_P1 and the first active pattern AP1 being patterned at an identical process level in a process of fabricating the semiconductor device according to some example embodiments. In proportion as the widths of the plurality of first sheets ST1 along the second direction are decreased as becoming far from the substrate 100, the width of the first portion 110_P1 may be also decreased.

According to some example embodiments, the side surface 110_SS2 of the second portion 110_P2 in the second direction D2 may be aligned with a side surface AP2_SS of the second active pattern AP2. The side surface 110_SS2 of the second portion 110_P2 in the second direction D2 being aligned with the side surface AP2_SS of the second active pattern AP2 may mean that the side surface 110_SS2 of the second portion 110_P2 in the second direction D2 and the side surface AP2_SS of the second active pattern AP2 are disposed on an identical plane. This may be due to the second portion 110_P2 and the second active pattern AP2 being patterned at an identical process level in the process of fabricating the semiconductor device according to some example embodiments. In proportion as widths of the plurality of second sheets ST2 along the second direction D2 are decreased as becoming far from the substrate 100, the width of the second portion 110_P2 may be also decreased.

According to some example embodiments, the intermediate insulation structure 110 may include multilayered films. For example, the intermediate insulation structure 110 may include a first film 111, a second film 112, and a third film 113. The first film 111, the second film 112, and the third film 113 may be stacked along the first direction D1. The first film 111 and the third film 113 may include an identical material. For example, the first film 111 and the third film 113 may include silicon oxycarbonitride (SiOCN). The second film 112 may include a material different from those of the first film 111 and the third film 113. The second film 112 may include a material same as the material of the first sheet ST1 and the second sheet ST2. For example, the second film 112 may include silicon or germanium. FIGS. 2 and 3 illustrate that the intermediate insulation structure 110 includes three films that are the first film 111, the second film 112, and the third film 113, but it is merely an example. The number of the multilayered films included in the intermediate insulation structure 110 may be vary depending on example embodiments.

According to some example embodiments, the first portion 110_P1 may include the first film 111 and at least a portion of the second film 112. The second portion 110_P2 may include the third film 113 and a portion of the second film 112. The second film 112 may overlap, along the second direction D2, the step formed between the first portion 110_P1 and the second portion 110_P2. The second film 112 may be disposed through the first portion 110_P1 and the second portion 110_P2.

FIGS. 3 and 4 illustrate that the first portion 110_P1 includes the first film 111 and the portion of the second film 112 and that the second portion 110_P2 includes the third film 113 and the portion of the second film 112, but it is merely an example. For example, the first portion 110_P1 may include the first film 111 alone, and the second portion 110_P2 may include the second film 112 and the third film 113.

According to some example embodiments, the gate separation structure 300 may be disposed between the first gate electrode 120 and the second gate electrode 220 in the first direction D1. The gate separation structure 300 may not overlap the first active pattern AP1 or the second active pattern AP2 along the first direction D1. The gate separation structure 300 may be disposed between first active patterns AP1 or second active patterns AP2 in the second direction D2. The gate separation structure 300 may be disposed in the filed region FR in which the first active pattern AP1 and the second active pattern AP2 are not disposed. The gate separation structure 300 may be disposed above the field insulation film 105.

According to some example embodiments, the gate separation structure 300 may be disposed at a side of the intermediate insulation structure 110 in the second direction D2. The gate separation structure 300 may be in contact with at least a portion of the side surface of the intermediate insulation structure 110. For example, the gate separation structure 300 may be in contact with at least a portion of the side surface 110_SS1 of the first portion 110_P1 of the intermediate insulation structure 110. The gate separation structure 300 may overlap at least a portion of the first active pattern AP1 along the second direction D2. The gate separation structure 300 may electrically insulate the first gate electrode 120 and the second gate electrode 220.

According to some example embodiments, a lower surface 300BS of the gate separation structure 300 and a lower surface of a lowermost first sheet ST1 may be disposed on an identical plane. However, it is merely an example. For example, the lower surface 300BS of the gate separation structure 300 may be disposed above the lowermost first sheet ST1.

According to some example embodiments, the gate separation structure 300 may include at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and a combination thereof.

According to some example embodiments, the gate separation structure 300 may include the first separator 310 and the second separator 320. The first separator 310 and the second separator 320 may be disposed along the first direction D1. The second separator 320 may be disposed on the first separator 310.

According to some example embodiments, the first separator 310 may be disposed on the first gate electrode 120. The first separator 310 may overlap the first active pattern AP1 along the second direction D2. At least a portion of the first separator 310 may be inserted into the first gate electrode 120 along the first direction D1. The first separator 310 may surround at least a portion of the second separator 320. For example, the first separator 310 may surround the second separator 320 which is inserted below the upper surface 310US of the first separator 310. The upper surface 310US of the first separator 310 may be disposed below the step between the first portion 110_P1 and the second portion 110_P2 of the intermediate insulation structure 110. The first separator 310 overlaps the first portion 110_P1 along the second direction D2, but may not overlap the second portion 110_P2.

According to some example embodiments, the first separator 310 and the second separator 320 may include different materials. For example, the first separator 310 may include silicon nitride (SiN), and the second separator 320 may include silicon oxide (SiO₂). However, it is merely an example. The first separator 310 and the second separator 320 may include an identical material.

According to some example embodiments, a width of the second separator 320 along the second direction D2 may be smaller than a width of the first separator 310 along the second direction D2. While the first separator 310 is in contact with the intermediate insulation structure 110 which is adjacent thereto along the second direction D2, the second separator 320 may be spaced apart from the intermediate insulation structure 110. Above the first separator 310, a groove portion GR may be formed between the second separator 320 and the intermediate insulation structure 110. The second gate insulation film 132 and the second gate electrode 220 may be inserted into the groove portion GR.

According to some example embodiments, a first source/drain contact 171 may be disposed below the first source/drain pattern 150. The first source/drain contact 171 may be connected to the first source/drain pattern 150. The first source/drain contact 171 may be connected to the first source/drain pattern 150 by penetrating the substrate 100. Along the first direction D1, the first source/drain contact 171 may be inserted into the first source/drain pattern 150 by penetrating the substrate 100 and the fin-shaped pattern 100a.

According to some example embodiments, the first source/drain contact 171 may include a first source/drain contact barrier film 171a and a first source/drain contact filling film 171b surrounded by the first source/drain contact barrier film 171a.

According to some example embodiments, a lower surface of the first source/drain contact barrier film 171a is illustrated as being positioned at a height substantially equal to that of a lower surface of the first source/drain contact filling film 171b, but it is merely an example. Unlike an illustration, the lower surface of the first source/drain contact barrier film 171a may be higher than the lower surface of the first source/drain contact filling film 171b.

According to some example embodiments, the first source/drain contact barrier film 171a may include, for example, at least one of tantalum (Ta), tantalum nitride (TaN), titanium (Ti), titanium nitride (TiN), titanium silicon nitride (TiSiN), ruthenium (Ru), cobalt (Co), nickel (Ni), nickel boron (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material. In the semiconductor device according to some example embodiments, the two-dimensional material may be a metallic material and/or a semiconductor material. The 2D material may include a two-dimensional allotrope or a two-dimensional compound and include, for example, at least one of graphene, molybdenum disulfide (MOS₂), molybdenum diselenide (MoSe₂), tungsten diselenide (WSe₂), and tungsten disulfide (WS₂), but it is merely an example. In other words, since the above-described 2D materials are mentioned merely as an example, the 2D material which may be included in the semiconductor device of the present disclosure is not limited to the above-described materials.

According to some example embodiments, the first source/drain contact filling film 171b may include, for example, at least one of aluminum (Al), tungsten (W), cobalt (Co), ruthenium (Ru), silver (Ag), gold (Au), manganese (Mn), and molybdenum (Mo).

According to some example embodiments, the first source/drain contact 171 is illustrated as including a plurality of conductive films, but it is merely an example. Unlike an illustration, the first source/drain contact 171 may be a single film.

According to some example embodiments, a second source/drain contact 172 may be disposed on the second source/drain pattern 250. The second source/drain contact 172 may be connected to the second source/drain pattern 250. The second source/drain contact 172 may be connected to the second source/drain pattern 250 by penetrating the second inter-layer insulation film 192 and the second source/drain etch stop film 162. The second source/drain contact 172 may completely penetrate the second inter-layer insulation film 192 along the first direction D1.

According to some example embodiments, the second inter-layer insulation film 192 does not cover an upper surface of the second source/drain contact 172. As an example, the upper surface of the second source/drain contact 172 may not protrude above the upper surface of the gate structure GS. The upper surface of the second source/drain contact 172 and the upper surface of the gate structure GS may be disposed on an identical plane. Unlike an illustration, as another example, the upper surface of the second source/drain contact 172 may protrude above the upper surface of the gate structure GS.

According to some example embodiments, the second source/drain contact 172 may include a second source/drain contact barrier film 172a and a second source/drain contact filling film 172b on the second source/drain contact barrier film 172a. The second source/drain contact barrier film 172a may be extended along a side surface and a floor surface of the second source/drain contact filling film 172b. Since being substantially identical to descriptions of the first source/drain contact barrier film 171a and the first source/drain contact filling film 171b, descriptions of the second source/drain contact barrier film 172a and the second source/drain contact filling film 172b will be omitted.

According to some example embodiments, a first etch stop film 193 and a third inter-layer insulation film 194 may be disposed on the second inter-layer insulation film 192, the gate structure GS, and the second source/drain contact 172. The first etch stop film 193 and the third inter-layer insulation film 194 may be sequentially stacked along the first direction D1.

According to some example embodiments, the first etch stop film 193 may include a material having an etch selectivity with respect to the third inter-layer insulation film 194. The first etch stop film 193 may include, for example, at least one of silicon nitride (SiN), silicon oxynitride (SiON), silicon oxycarbonitride (SiOCN), silicon boronitride (SiBN), silicon oxyboronitride (SiOBN), silicon oxycarbide (SiOC), aluminum oxide (AlO), aluminum nitride (AlN), and aluminum oxycarbide (AlOC), and a combination thereof. The first etch stop film 193 is illustrated as a single film, but it is merely an example. Unlike an illustration, the first etch stop film 193 may not be formed. The third inter-layer insulation film 194 may include, for example, at least one of silicon oxide, silicon nitride, silicon carbonitride, silicon oxynitride, and a low-permittivity material.

According to some example embodiments, a first gate contact 181 may be disposed below the first gate electrode 120. The first gate contact 181 may be connected to the first gate electrode 120 by penetrating the substrate 100 and the fin-shaped pattern 100a.

According to some example embodiments, the first gate contact 181 may include a first gate contact barrier film 181a and a first gate contact filling film 181b surrounded by the first gate contact barrier film 181a. A description for a material included in the first gate contact barrier film 181a and the first gate contact filling film 181b may be identical to a description for a material included in the first source/drain contact barrier film 171a and the first source/drain contact filling film 171b.

According to some example embodiments, a second gate contact 182 may be disposed above the second gate electrode 220. The second gate contact 182 may be connected to the second gate electrode 220 by penetrating the gate capping film 125. The second gate contact 182 may penetrate the first etch stop film 193 and the third inter-layer insulation film 194.

As an example, an upper surface of the second gate contact 182 may protrude above the upper surface of the gate structure GS. Unlike an illustration, as another example, the upper surface of the second gate contact 182 and the upper surface of the gate structure GS may be disposed on an identical plane.

According to some example embodiments, the second gate contact 182 may include a second gate contact barrier film 182a and a second gate contact filling film 182b on the first gate contact barrier film 182a. A description for a material included in the second gate contact barrier film 182a and the second gate contact filling film 182b may be identical to the description for the material included in the first source/drain contact barrier film 171a and the first source/drain contact filling film 171b.

FIG. 2 illustrate that a lower surface of the first source/drain contact 171 and a lower surface of the first gate contact 181 are disposed on an identical plane, but it is merely an example. As an example, the lower surface of the first source/drain contact 171 may be disposed above the lower surface of the first gate contact 181. As another example, the lower surface of the first source/drain contact 171 may be disposed below the lower surface of the first gate contact 181.

According to some example embodiments, a wiring via 175 may be disposed in the third inter-layer insulation film 194. The wiring via 175 may be directly connected to the second source/drain contact 172 by penetrating the first etch stop film 193. The wiring via 175 may be connected to the second source/drain contact 172.

According to some example embodiments, the wiring via 175 may include a via barrier film 175a and a via filling film 175b. The via barrier film 175a may be extended along a side wall and a floor surface of the via filling film 175b. The via barrier film 175a may include, for example, at least one of tantalum (Ta), tantalum nitride (TaN), titanium (Ti), titanium nitride (TiN), titanium silicon nitride (TISIN), nickel (Ni), nickel boron (NiB), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), rhodium (Rh), and a two-dimensional (2D) material. The via filling film 175b may include, for example, at least one of aluminum (Al), tungsten (W), cobalt (Co), ruthenium (Ru), copper (Cu), silver (Ag), gold (Au), manganese (Mn), and molybdenum (Mo).

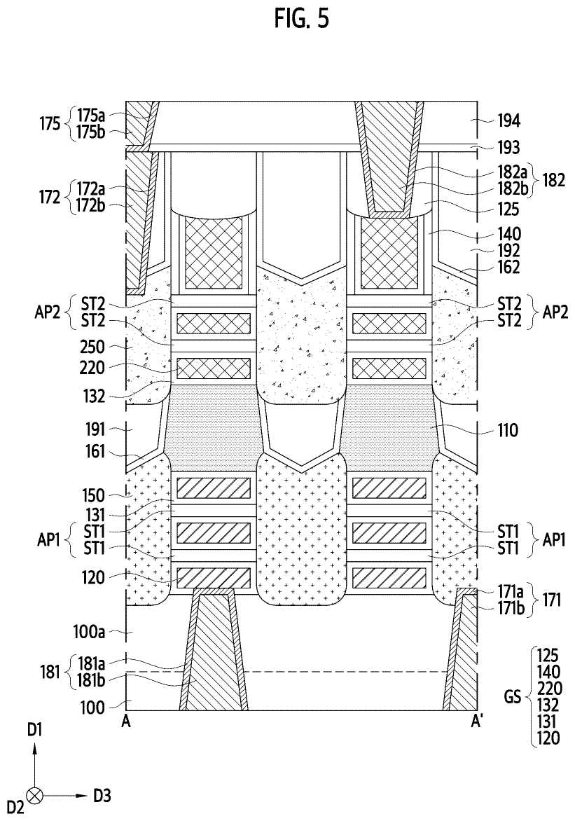

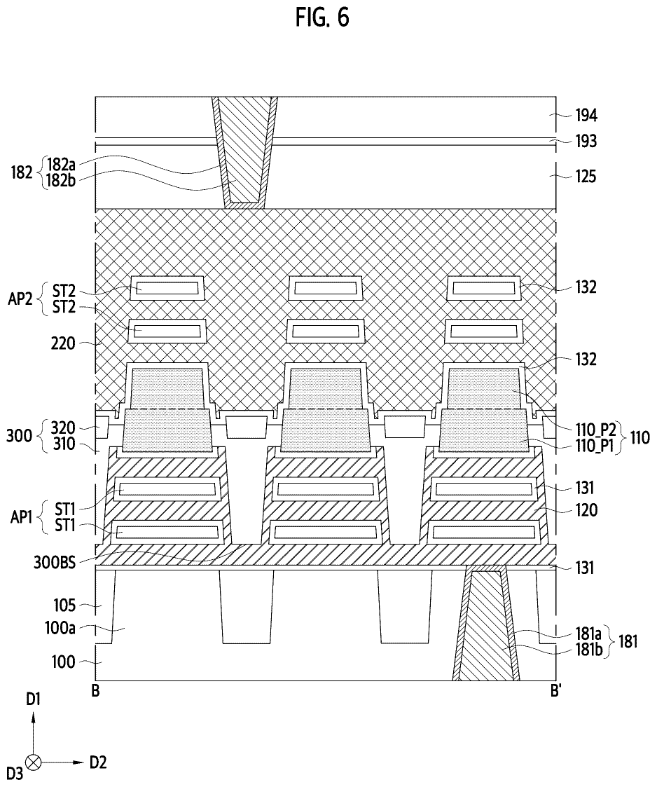

FIG. 5 is a diagram illustrating a cross section taken along line A-A′ of FIG. 1 for describing a semiconductor device according to other example embodiments. FIG. 6 is a diagram illustrating a cross section taken along line B-B′ of FIG. 1 for describing the semiconductor device according to the other example embodiments. In order to assist in understanding the present disclosure, a description will mainly focus on a point different from that described above with reference to FIGS. 1 through 4.

Referring to FIGS. 5 and 6, the intermediate insulation structure 110 may include a single film. For example, the intermediate insulation structure 110 may include at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and a combination thereof. The first portion 110_P1 and the second portion 110_P2 of the intermediate insulation structure 110 may include an identical material.

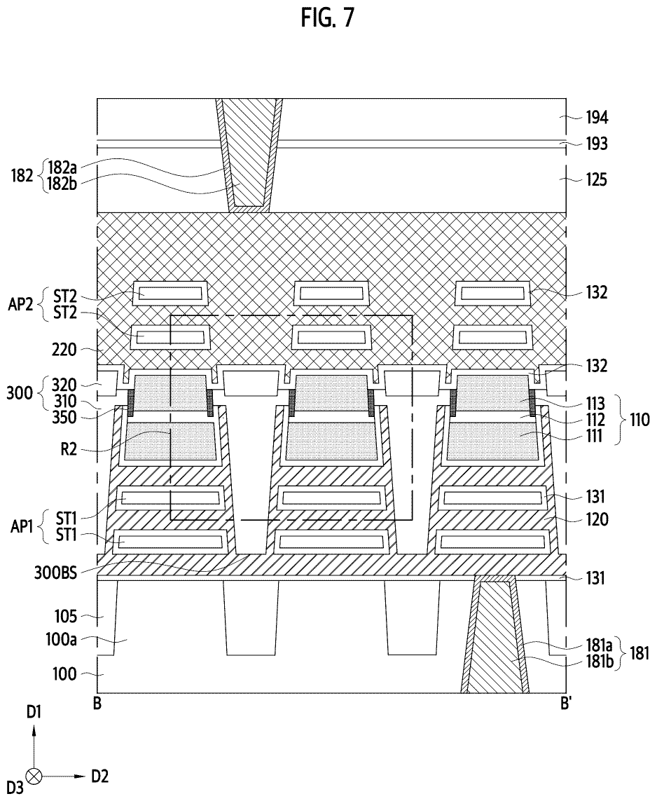

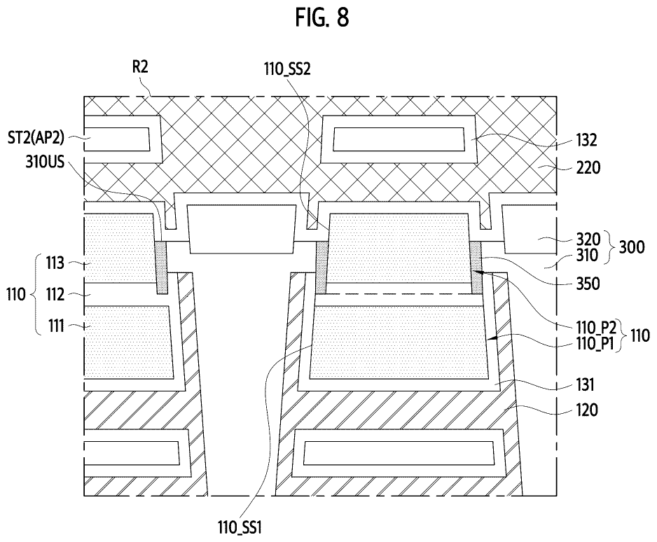

FIG. 7 is a diagram illustrating a cross section taken along line B-B′ of FIG. 1 for describing a semiconductor device according to still other example embodiments. FIG. 8 is an enlarged diagram illustrating section R2 of FIG. 7. In order to assist in understanding the present disclosure, a description will mainly focus on a point different from that described above with reference to FIGS. 1 through 4.

Referring to FIGS. 7 and 8, a protective film 350 may be disposed at a side of the intermediate insulation structure 110. The protective film 350 may be disposed on the first portion 110_P1 of the intermediate insulation structure 110. The protective film 350 may be disposed at a side of the second portion 110_P2 of the intermediate insulation structure 110. On the first portion 110_P1, the protective film 350 may cover at least a portion of the side surface 110_SS2 of the second portion 110_P2. An outer side surface of the protective film 350 in the second direction D2 and the side surface 110_SS1 of the first portion 110_P1 may be disposed on an identical plane.

According to some example embodiments, the gate separation structure 300 may be in contact with the protective film 350. The first separator 310 of the gate separation structure 300 may cover at least a portion of the protective film 350. The upper surface 310US of the first separator 310 may be disposed above a step between the first portion 110_P1 and the second portion 110_P2 of the intermediate insulation structure 110. The first separator 310 may overlap the first portion 110_P1 and the second portion 110_P2 along the second direction D2. The upper surface 310US of the first separator 310 and an upper surface of the protective film 350 may be disposed on an identical plane. However, it is merely an example. For example, the upper surface 310US of the first separator 310 may be disposed above the upper surface of the protective film 350. In such a case, a groove portion may be formed by the first separator 310, the protective film 350, and the intermediate insulation structure 110. The second gate insulation film 132 and the second gate electrode 220 may be inserted into the groove portion.

According to some example embodiments, the protective film 350 may be surrounded by the first portion 110_P1, the second portion 110_P2, the first gate insulation film 131, the gate separation structure 300, and the second gate insulation film 132. A thickness of the protective film 350 along the second direction may be 2 to 4 nanometers (nm). The protective film 350 may include at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and a combination thereof.

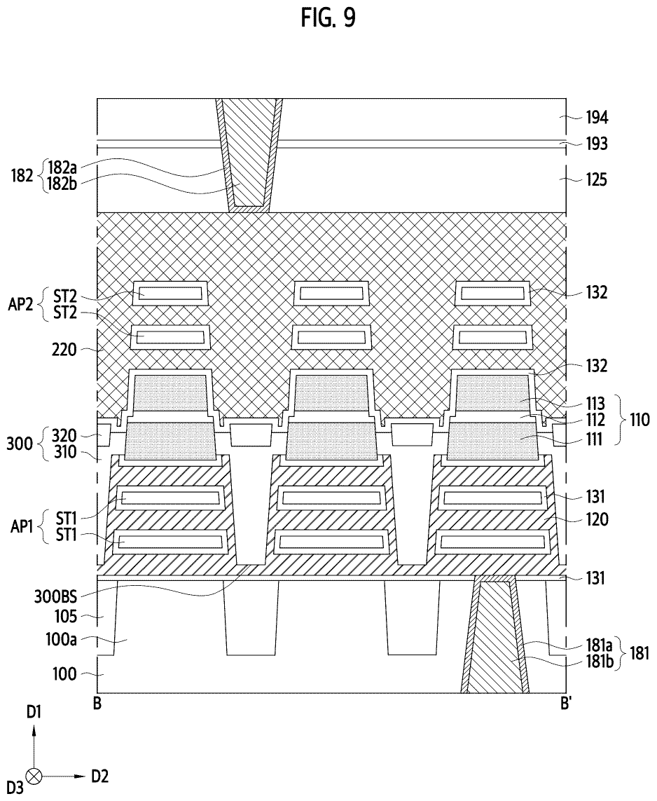

FIG. 9 is a diagram illustrating a cross section taken along line B-B′ of FIG. 1 for describing a semiconductor device according to still other example embodiments. In order to assist in understanding the present disclosure, a description will mainly focus on a point different from that described above with reference to FIGS. 1 through 4.

Referring to FIG. 9, the lower surface 300BS of the gate separation structure 300 may be disposed to be lower than a lower surface of the lowermost first sheet ST1. However, it is merely an example. The lower surface 300BS of the gate separation structure 300 may be disposed between the lower surface of the lowermost first sheet ST1 and the first gate insulation film 131 which covers the field insulation film 105.

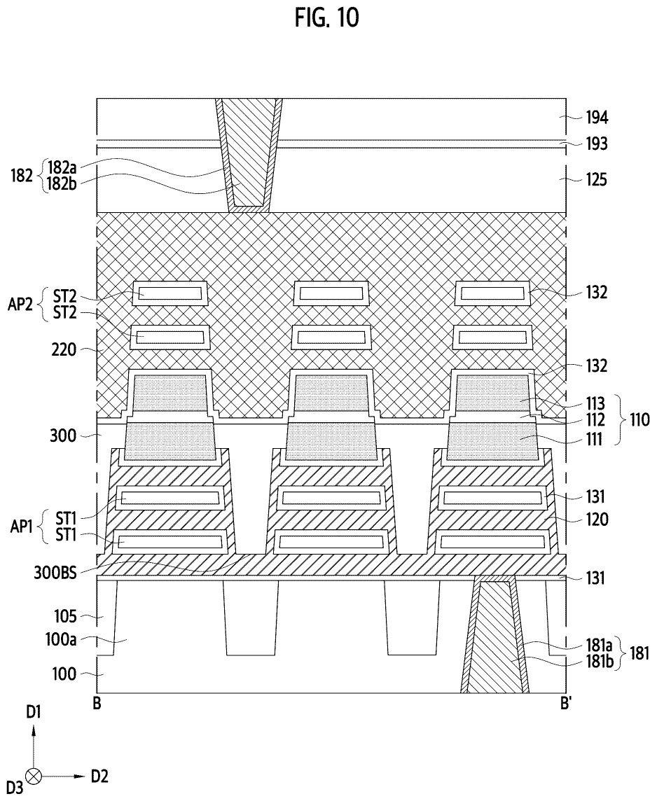

FIG. 10 is a diagram illustrating a cross section taken along line B-B′ of FIG. 1 for describing a semiconductor device according to still other example embodiments. In order to assist in understanding the present disclosure, a description will mainly focus on a point different from that described above with reference to FIGS. 1 through 4.

Referring to FIG. 10, the gate separation structure 300 may include a single film. A side surface of the gate separation structure 300 in the second direction D2 may be in contact with the intermediate insulation structure 110. An upper surface of the gate separation structure 300 may be disposed to be parallel to a surface of the substrate 100, not protrude toward the second gate electrode 220. The groove portion GR (of FIG. 4) may not be formed between the gate separation structure 300 and the intermediate insulation structure 110. The second gate insulation film 132 may be extended along the upper surface of the gate separation structure 300 between intermediate insulation structures 110 which are spaced apart along the second direction D2.

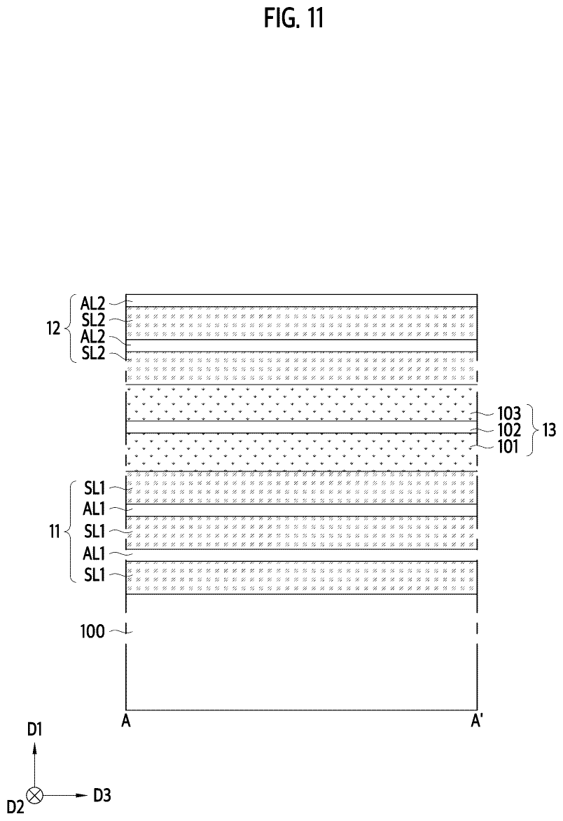

FIGS. 11 through 35 are diagrams illustrating an intermediate operation for describing a method for fabricating a semiconductor device illustrated in FIGS. 2 and 3.

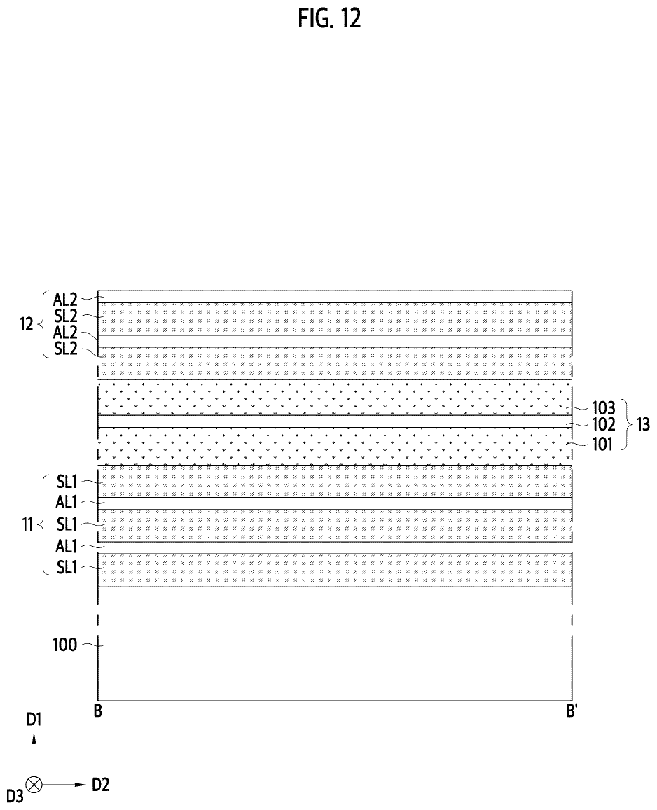

Referring to FIGS. 11 and 12, a first stack 11, a third stack 13, and a second stack 12 may be formed in sequential order above the substrate 100. The first stack 11 may include a first active layer AL1 and a first sacrificial layer SL1 that are alternately stacked. The second stack 12 may include a second active layer AL2 and a second sacrificial layer SL2 that are alternately stacked. The third stack 13 may be formed between the first stack 11 and the second stack 12. The third stack 13 may include an intermediate sacrificial film 101, a second pre-film 102, and a second intermediate sacrificial film 103.

Specifically, the first stack 11, the third stack 13, and the second stack 12 may be formed across the active region AR (of FIG. 1) and the field region FR (of FIG. 1). The first active layer AL1, the second active layer AL2, and the second pre-film 102 may include an identical material. For example, the first active layer AL1, the second active layer AL2, and the second pre-film 102 may include silicon (Si). The first sacrificial layer SL1 and the second sacrificial layer SL2 may include an identical material and include a material different from those of the first active layer AL1, the second active layer AL2, and the second pre-film 102. For example, the first sacrificial layer SL1 and the second sacrificial layer SL2 may include silicon germanium (SiGe). However, it is merely an example. The first intermediate sacrificial film 101 and the second intermediate sacrificial film 103 may include an identical material. The first intermediate sacrificial film 101 and the second intermediate sacrificial film 103 may include a material different from that of the second pre-film 102. For example, the first intermediate sacrificial film 101 and the second intermediate sacrificial film 103 may include a high concentration of silicon germanium (SiGe). The first active layer AL1, the second active layer AL2, and the second pre-film 102 may include a material identical to that of the substrate 100, but it is merely an example.

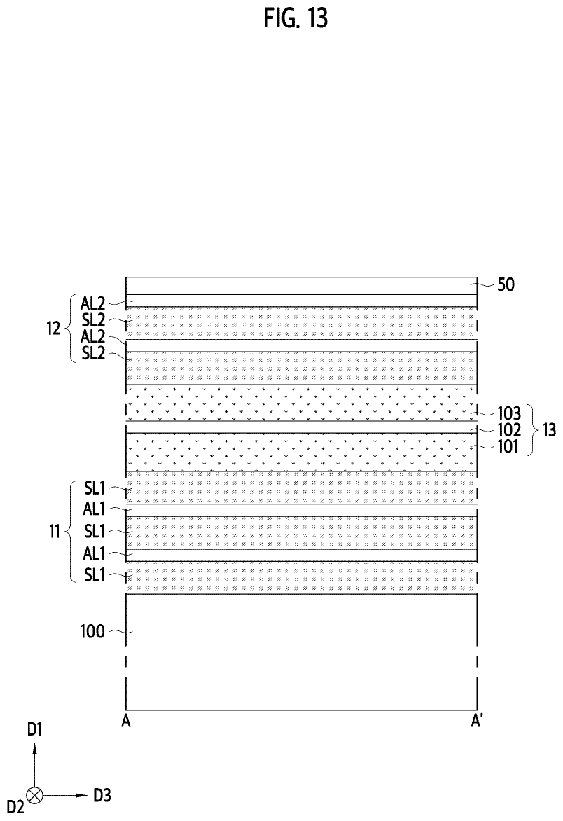

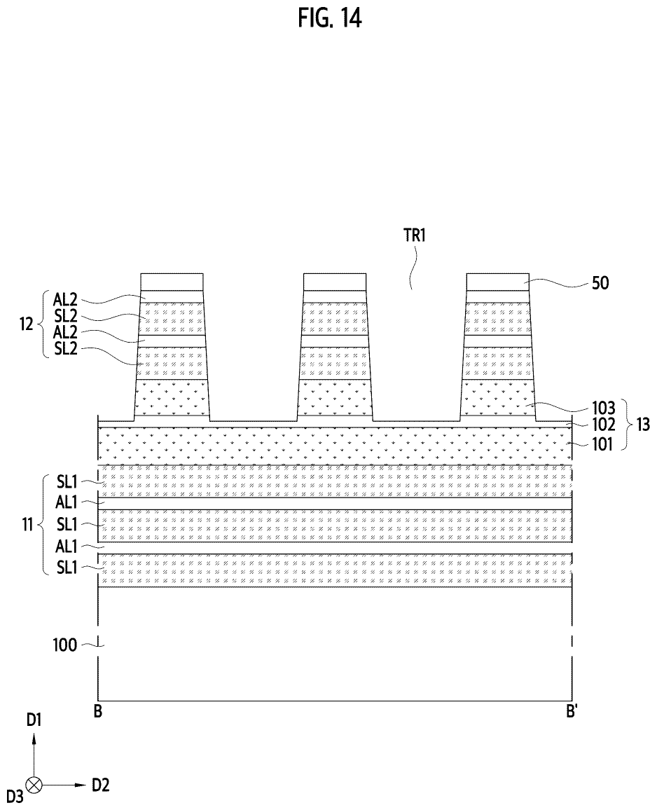

Referring to FIGS. 13 and 14, a mask 50 may be formed on the second stack 12, and the second stack 12 and an upper portion of the third stack 13 may be patterned by using the mask 50. The patterned upper portion of the third stack 13 may correspond to a shape of the second portion 110_P2 (of FIG. 4) of the intermediate insulation structure 110 (of FIG. 3). In order to separate the second stack 12 apart along the second direction D2, a portion of the second stack 12 may be removed, so that a first trench TR1 may be formed. The upper portion of the third stack 13 may be partially patterned together with the second stack 12. For example, at least portions of the second intermediate sacrificial film 103 and the second pre-film 102 of the third stack 13 may be patterned. A surface of the second pre-film 102 may be exposed in the first trench TR1. The mask 50 may include, for example, at least one of silicon nitride, polysilicon, a spin-on hardmask (SOH) material, and a combination thereof.

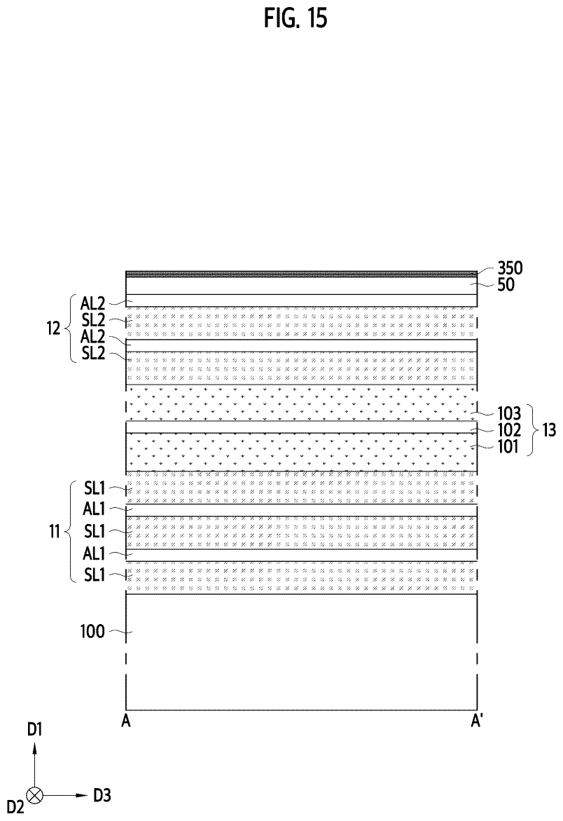

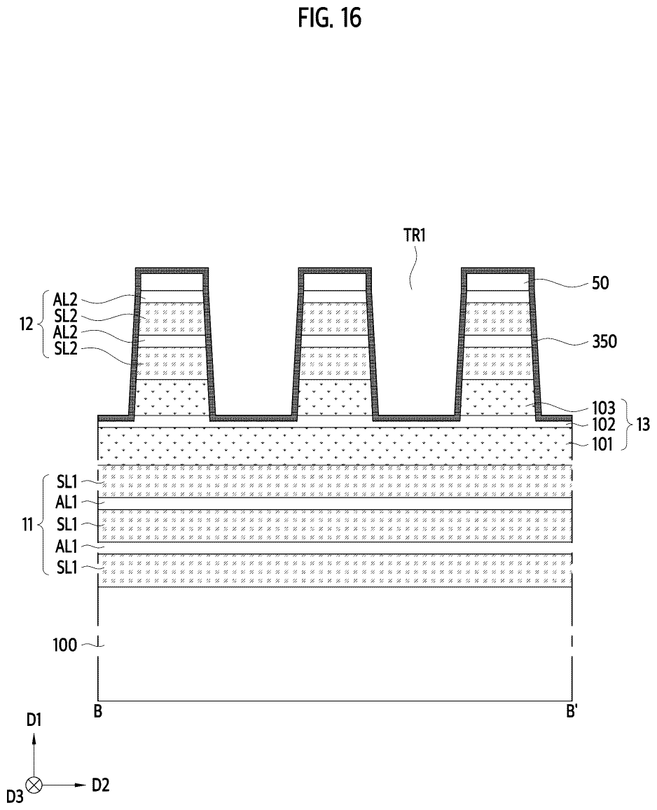

Referring to FIGS. 15 and 16, the protective film 350 may be formed on the mask 50, the second stack 12, and the third stack 13. The protective film 350 may be extended along surficial profiles of the first trench TR1, the second stack 12, and the third stack 13. In the first trench TR1, the protective film 350 may cover a side surface of the second stack 12 in the second direction D2. The protective film 350 may cover a side surface of the second sacrificial layer SL2 and a side surface of the second active layer AL2, which are in the second direction D2.

According to some example embodiments, the protective film 350 may include at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and a combination thereof.

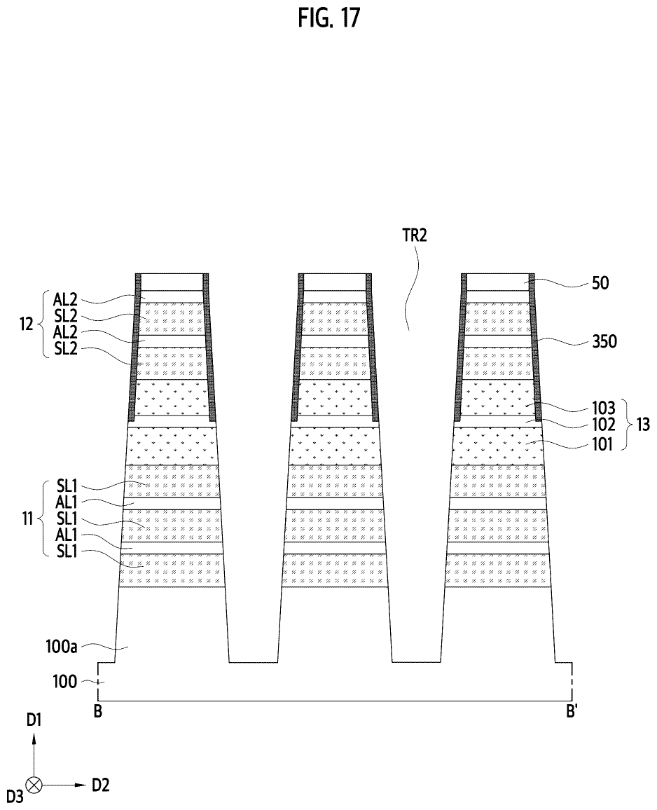

Referring to FIG. 17, the substrate 100, the first stack 11, and a lower portion of the third stack 13 may be patterned by using the second stack 12 and the third stack 13 which are separated apart along the second direction D2 and covered with the protective film 350. A shape of the lower portion of the third stack 13 may correspond to a shape of the first portion 110_P1 (of FIG. 4) of the intermediate insulation structure 110 (of FIG. 3). The substrate 100 may be patterned, so that the fin-shaped pattern 100a may be formed. As portions of the first stack 11 and the third stack 13, which overlaps the first trench TR (of FIG. 16) along the first direction D1, are removed, a second trench TR2 may be formed. For example, at least portions of the first intermediate sacrificial film 101 and the second pre-film 102 of the third stack 13 may be patterned. In a process of forming the second trench TR2, at least a portion of the protective film 350 on the mask 50 may be removed.

According to some example embodiments, the patterned upper portion of the third stack 13 may be covered with the protective film 350, and the lower portion of the third stack 13 may not be covered with the protective film 350. The second stack 12 and the upper portion of the third stack 13 may be patterned by using the mask 50. The lower portion of the third stack 13, which is the first intermediate sacrificial film 101 and a portion of the second pre-film 102, and the first stack 11 may be patterned by using the second stack 12 and the upper portion of the third stack 13, which are covered with the protective film 350, as a mask. Thus, the lower portion of the third stack 13 and the first stack 11 which are patterned by using, as the mask, the second stack 12 and the upper portion of the third stack 13 to which the protective film 350 is additionally formed may have widths along the second direction D2, which are larger than those of the second stack 12 and the upper portion of the third stack 13 which are patterned by using the mask 50 alone before the protective film 350 is formed.

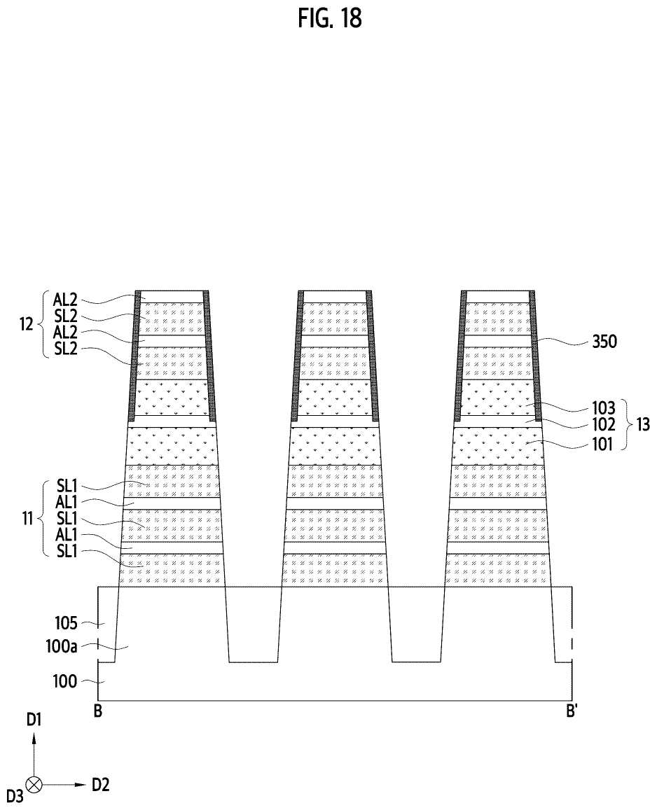

Referring to FIG. 18, the field insulation film 105 may be formed at a side of the fin-shaped pattern 100a in the second trench TR2 (of FIG. 17).

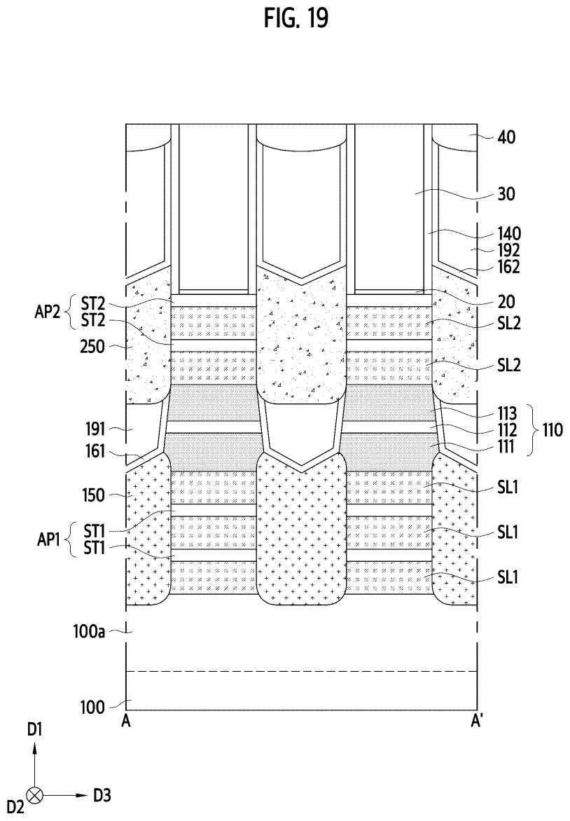

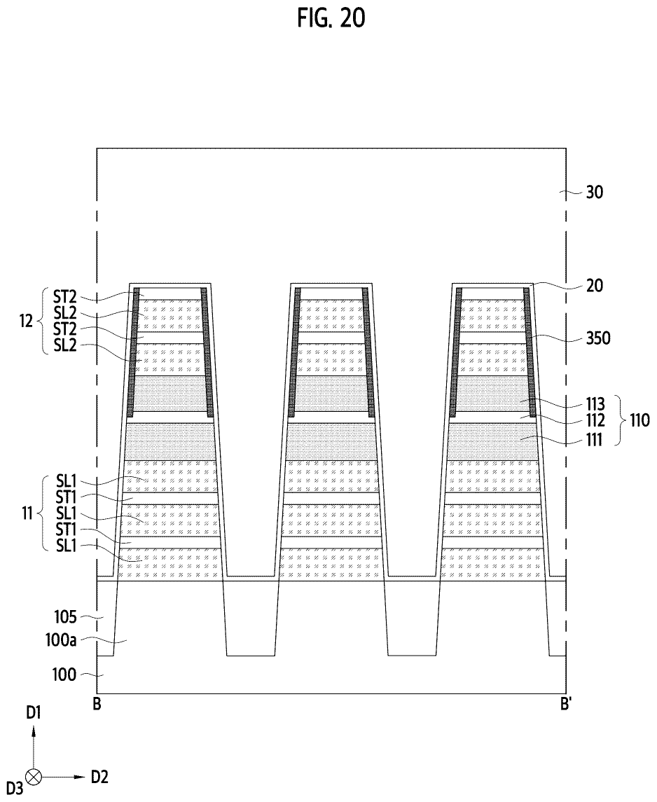

Referring to FIGS. 19 and 20, the gate spacer 140, a patterning protection film 20, and a molding film 30 may be formed above the first stack 11, the second stack 12, and the third stack 13 which are patterned along the second direction D2. The patterning protection film 20 may be extended along profiles of the first stack 11, the second stack 12, and the third stack 13 which are patterned. The patterning protection film 20 may include, for example, silicon oxide. The molding film 30 may include, for example, at least one of silicon oxide, silicon nitride, silicon oxynitride, and a low-permittivity material.

Then, the first intermediate sacrificial film 101 (of FIG. 18) and the second intermediate sacrificial film 103 (of FIG. 18) of the third stack 13 (of FIG. 18) may be removed and replaced with the first film 111 and the third film 113. For example, the first intermediate sacrificial film 101 (of FIG. 18) and the second intermediate sacrificial film 103 (of FIG. 18) which include the high concentration of silicon germanium (SiGe) may be removed, and the first film 111 and the third film 113 which include silicon oxycarbonitride (SiOCN) may be formed. As the first intermediate sacrificial film 101 (of FIG. 18) and the second intermediate sacrificial film 103 (of FIG. 18) of the third stack 13 (of FIG. 18) may be removed and replaced with the first film 111 and third film 113, and as the second pre-film 102 (of FIG. 18) is patterned so that the second film 112 is formed, the intermediate insulation structure 110 may be formed.

Then, the first stack 11 may be patterned along the third direction D3, and the first source/drain pattern 150 may be formed. The third stack 13 may be patterned along the third direction D3, and the first source/drain etch stop film 161 and the first inter-layer insulation film 191 may be formed. The second stack 12 may be patterned along the third direction D3, and the second source/drain pattern 250 may be formed. The first source/drain pattern 150, the first source/drain etch stop film 161, the first inter-layer insulation film 191, and the second source/drain pattern 250 may be formed in sequential order.

According to some example embodiments, the second source/drain etch stop film 162 and the second inter-layer insulation film 192 may be formed above the second source/drain pattern 250. A protective capping film 40 may be formed on the second source/drain etch stop film 162 and the second inter-layer insulation film 192. The protective capping film 40 may protect the second source/drain etch stop film 162 and the second inter-layer insulation film 192 so that the second source/drain etch stop film 162 and the second inter-layer insulation film 192 are not removed during a patterning process. The protective capping film 40 may include, for example, at least one of silicon nitride (SiN), silicon oxynitride (SiON), silicon oxide (SiO₂), silicon oxycarbonitride (SiOCN), silicon boronitride (SiBN), silicon oxyboronitride (SiOBN), silicon oxycarbide (SiOC), and a combination thereof.

According to some example embodiments, the first active layer AL1 (of FIG. 15) which is extended along the third direction D3 may be patterned, so that the first active pattern AP1 which includes the first sheet ST1 may be formed. The first sacrificial layer SL1 and the first active layer AL1 (of FIG. 15) may be patterned, and the first source/drain pattern 150 may be formed between the first sacrificial layer SL1 and the first active pattern AP1 which are spaced apart along the third direction D3. As the first sacrificial layer SL1 and the first active layer AL1 (of FIG. 15) are patterned, the first film 111, the second film 112, and the third film 113 may be patterned together. The second pre-film 102 (of FIG. 18) may be patterned, so that the second film 112 may be formed. Materials included in the second pre-film 102 (of FIG. 18) and the second film 112 may be identical.

According to some example embodiments, the first source/drain etch stop film 161 and the first inter-layer insulation film 191 may be formed above the first source/drain pattern 150. The first source/drain etch stop film 161 and the first inter-layer insulation film 191 may be formed in an area in which the first film 111, the second film 113, and the third film 113 extended along the third direction D3 are patterned.

According to some example embodiments, the second active layer AL2 (of FIG. 15) which is extended along the third direction D3 may be patterned, so that the second active pattern AP2 which includes the second sheet ST2 may be formed. The second sacrificial layer SL2 and the second active layer AL2 (of FIG. 15) may be patterned, and the second source/drain pattern 250 may be formed between the second sacrificial layer SL2 and the second active pattern AP2 which are spaced apart along the third direction D3.

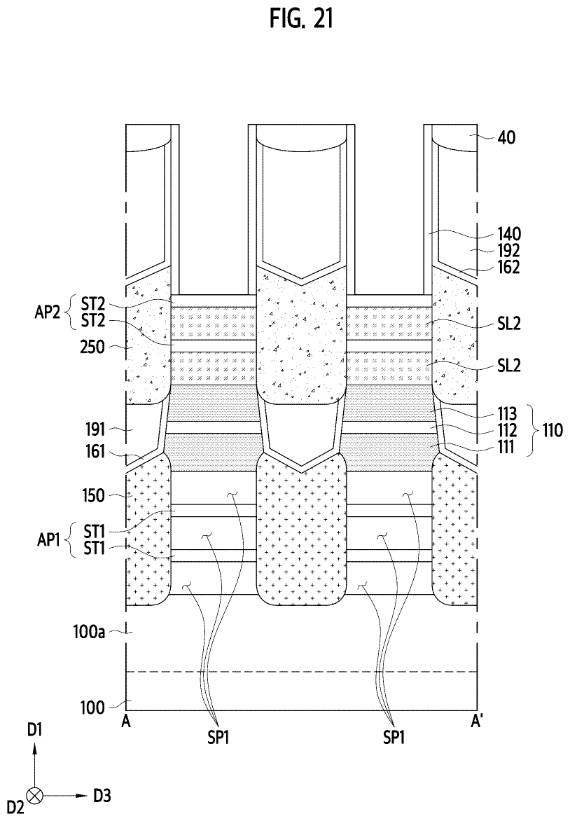

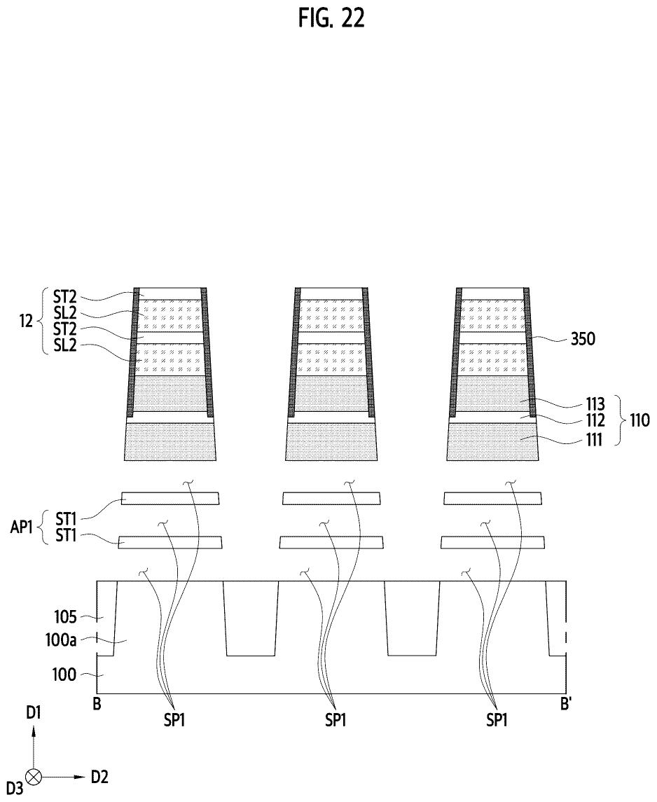

Referring to FIGS. 21 and 22, the patterning protection film 20 (of FIGS. 19 and 20) and the molding film 30 (of FIGS. 19 and 20) may be removed, and the first sacrificial layer SL1 (of FIGS. 19 and 20) which is exposed may be removed. When the patterning protection film 20 (of FIGS. 19 and 20) and the molding film 30 (of FIGS. 19 and 20) are removed, the side surface of the first sacrificial layer SL1 (of FIGS. 19 and 20) in the second direction D2 may be exposed. The exposed first sacrificial layer SL1 (of FIGS. 19 and 20) may be, for example, removed through a wet etching process. As the first sacrificial layer SL1 (of FIGS. 19 and 20) is removed, a first space SP1 may be formed above and below the first active pattern AP1. Although the patterning protection film 20 (of FIGS. 19 and 20) and the molding film 30 (of FIGS. 19 and 20) are removed, the second sacrificial layer SL2 which is covered with the protective film 350 may not be removed.

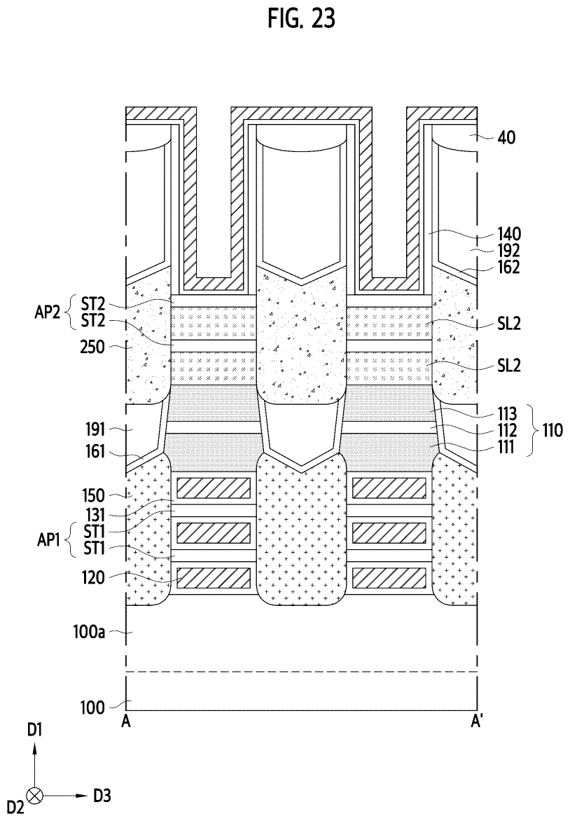

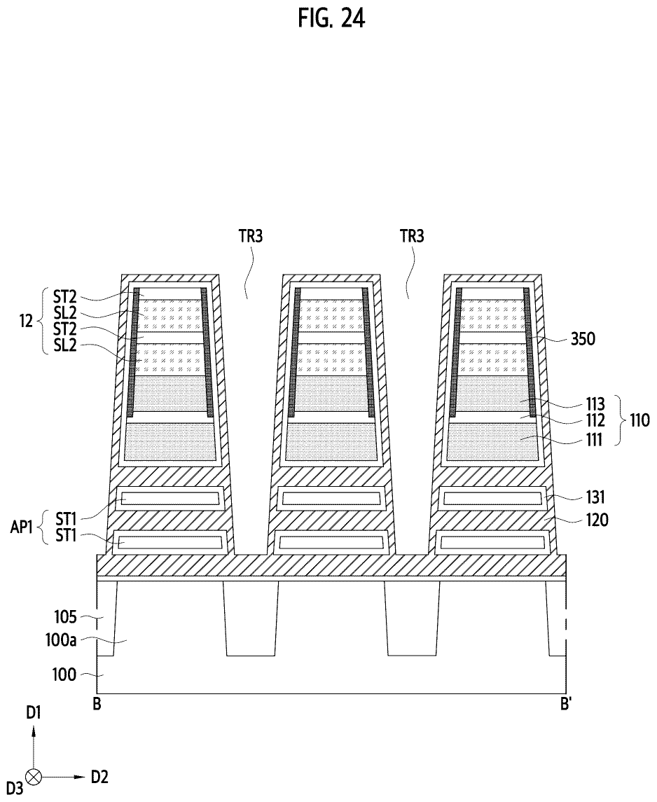

Referring to FIGS. 23 and 24, the first gate insulation film 131 and the first gate electrode 120 may be formed. The first gate insulation film 131 and the first gate electrode 120 may surround the first active pattern AP1. The first gate insulation film 131 and the first gate electrode 120 may be formed on the first active pattern AP1. The first gate insulation film 131 and the first gate electrode 120 may fill the first space SP1 (of FIGS. 21 and 22). The first gate insulation film 131 and the first gate electrode 120 may surround the intermediate insulation structure 110, the protective film 350, and the second stack 12.

According to some example embodiments, since the first gate insulation film 131 and the first gate electrode 120 are formed to be conformal along surfaces of the first active pattern AP1, the intermediate insulation structure 110, the protective film 350, and the second stack 12, a third trench TR3 may be formed on the first gate electrode 120. On the first gate electrode 120, the third trench TR3 may be formed between the first active patterns AP1, between the intermediate insulation structures 110, between protective films 350, and between second stacks 12, all of which are spaced apart along the second direction D2.

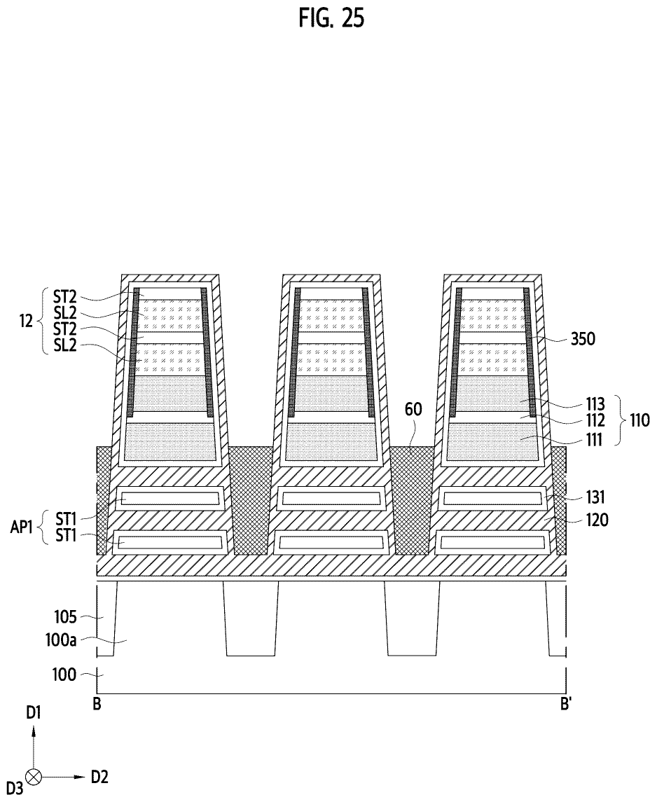

Referring to FIG. 25, a blocking film 60 may be formed in the third trench TR3 (of FIG. 24). The blocking film 60 may be formed on the first gate electrode 120 in the third trench TR3 (of FIG. 24). An upper surface of the blocking film 60 may be disposed below a lower surface of the protective film 350. The blocking film 60 may include a bottom anti-reflection coating (BARC) material.

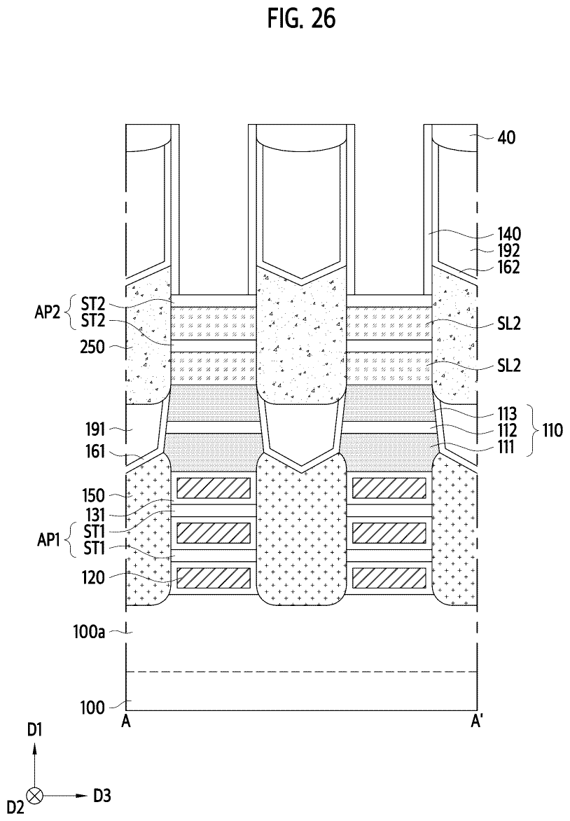

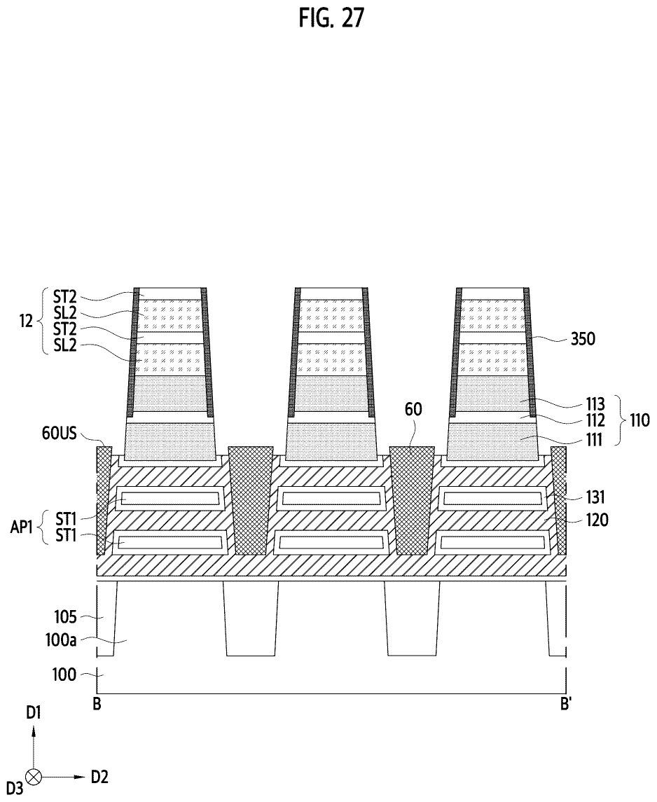

Referring to FIGS. 26 and 27, other portions of the first gate insulation film 131 and the first gate electrode 120, which are not covered with the blocking film 60, may be removed. As the other portions of the first gate insulation film 131 and the first gate electrode 120, which are not covered with the blocking film 60, are removed, the intermediate insulation structure 110, the protective film 350, and the second sheet ST2 may be exposed. At least portions of the first gate insulation film 131 and the first gate electrode 120 may be removed, so that the first gate insulation film 131 and the first gate electrode 120 may be disposed below an upper surface 60US of the blocking film 60.

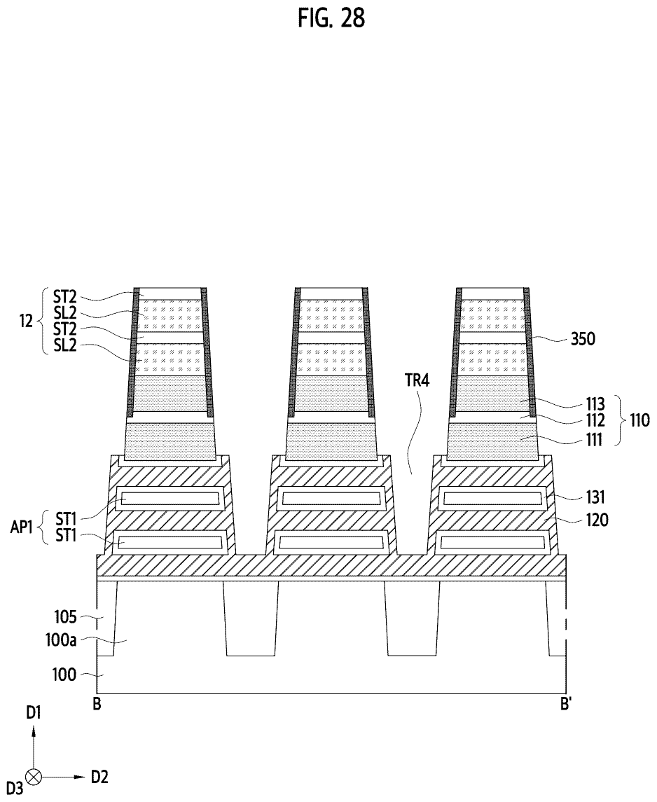

Referring to FIG. 28, the blocking film 60 may be removed. As the blocking film 60 is removed, a fourth trench TR4 may be formed on the first gate electrode 120.

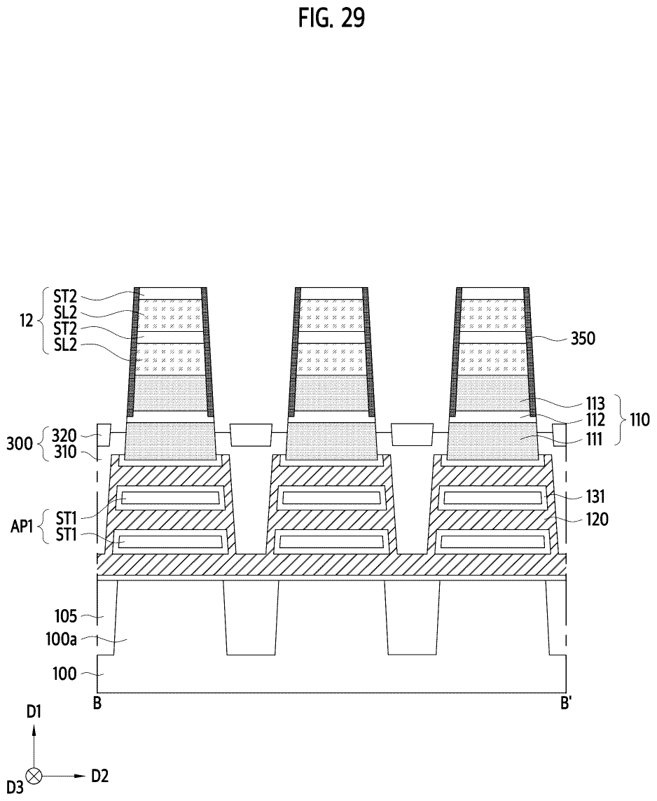

Referring to FIG. 29, the gate separation structure 300 may be formed. The gate separation structure 300 may be formed in the fourth trench TR4 (of FIG. 28). The first separator 310 may be formed along a side surface of the intermediate insulation structure 110 and the fourth trench TR4 (of FIG. 28), and the second separator 320 may be formed on the first separator 310. The gate separation structure 300 may be formed below the protective film 350.

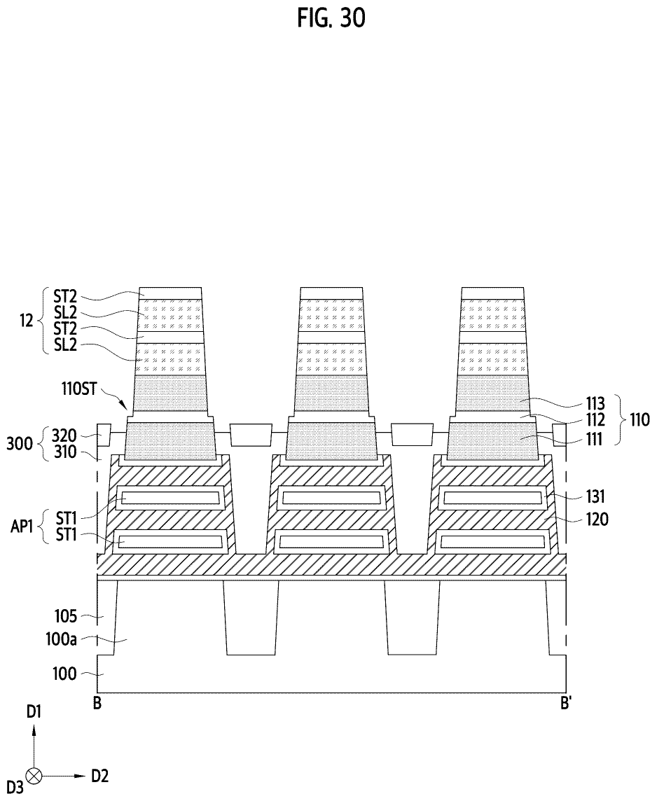

Referring to FIG. 30, the protective film 350 (of FIG. 29) may be removed. As the protective film 350 (of FIG. 29) is removed, a step 110ST may be formed on the side surface of the intermediate insulation structure 110. The protective film 350 (of FIG. 29) may be removed, so that the second sacrificial layer SL2 and the second sheet ST2 of the second stack 12 may be exposed.

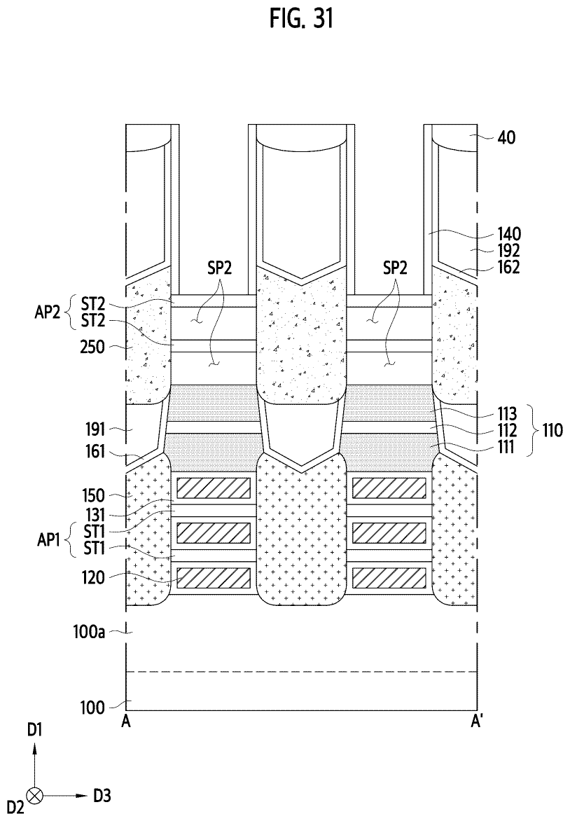

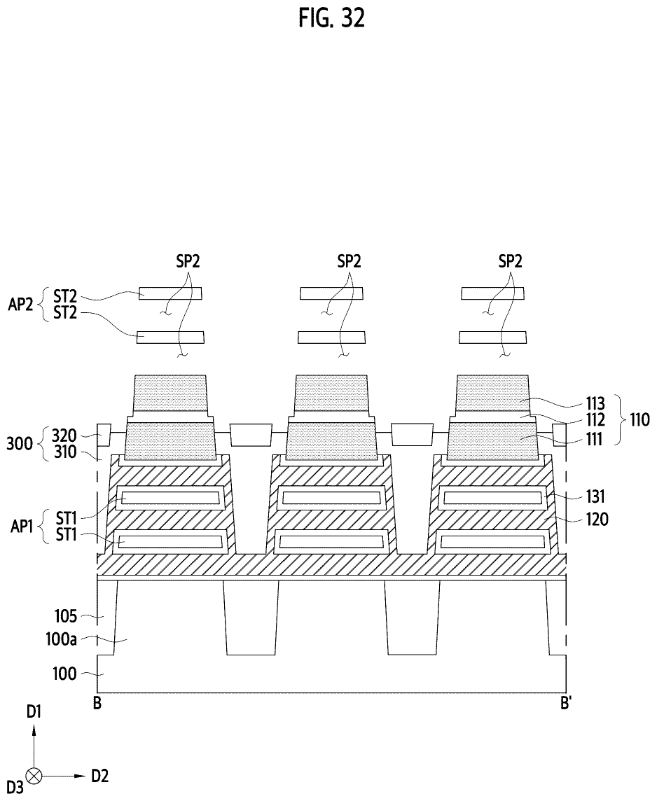

Referring to FIGS. 31 and 32, the second sacrificial layer SL2 (of FIG. 30) may be removed. The second sacrificial layer SL2 (of FIG. 30) may be, for example, removed through a wet etching process. As the second sacrificial layer SL2 (of FIG. 30) is removed, a second space SP2 may be formed above and below the second active pattern AP2.

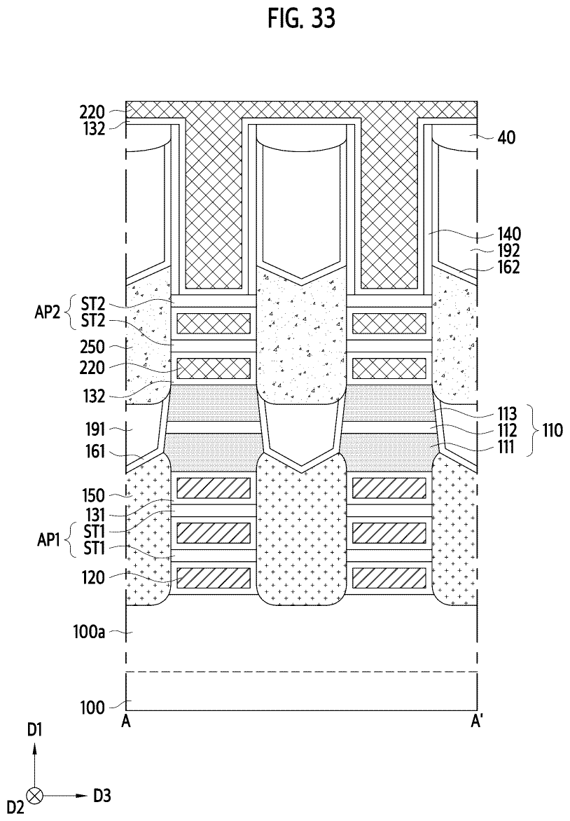

Referring to FIG. 33, the second gate insulation film 132 and the second gate electrode 220 may be formed. The second gate insulation film 132 and the second gate electrode 220 may surround the second active pattern AP2. The second gate insulation film 132 and the second gate electrode 220 may fill the second space SP2 (of FIGS. 31 and 32).

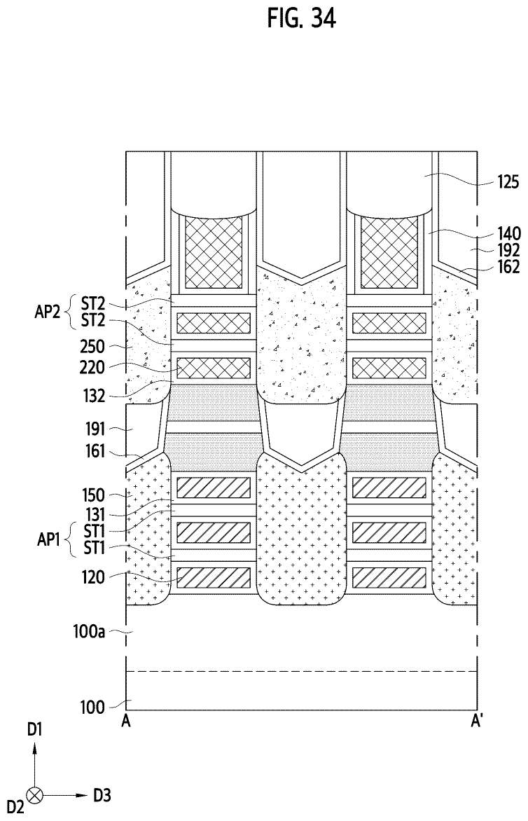

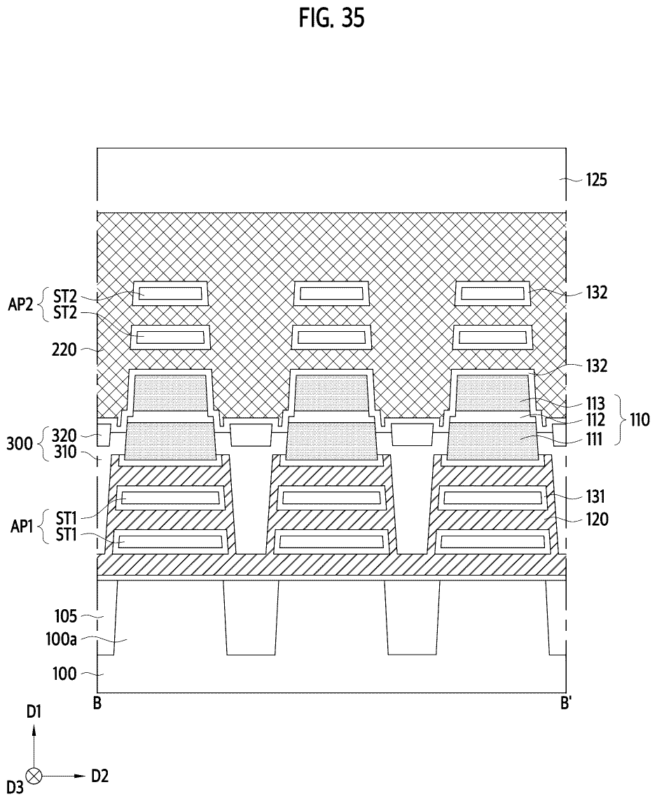

Referring to FIGS. 34 and 35, a portion of the second gate insulation film 220 may be removed, and the gate capping film 125 may be formed above the second gate electrode 220. As the gate capping film 125 is formed, the protective capping film 40 (of FIG. 33) may be removed through a planarization process. For example, as the protective capping film 40 (of FIG. 33) is removed through a chemical mechanical polishing process, upper surfaces of the gate capping film 125 and the second inter-layer insulation film 192 may be disposed on an identical plane.

Then, referring to FIGS. 2 and 3, the first source/drain contact 171 which is connected to the first source/drain pattern 150, the second source/drain contact 172 which is connected to the second source/drain pattern 250, the first gate contact 181 which is connected to the first gate electrode 120, and the second gate contact 182 which is connected to the second gate electrode 220 may be formed.

According to some example embodiments, the protective film 350 may be used, so that the second sacrificial layer SL2 (of FIG. 20) may not be removed and so that the first sacrificial layer SL1 (of FIG. 20) may be selectively removed. Thus, since the first gate electrode 120 and the second gate electrode 220 may be separately formed, a lower transistor formed with the first active pattern AP1, the first source/drain pattern 150, and the first gate electrode 120 and an upper transistor formed with the second active pattern AP2, the second source/drain pattern 250, and the second gate electrode 220 may be separately controlled, so that integration density of the semiconductor device may be improved. In addition, since a threshold voltage control capability of each gate electrode is improved because the first gate electrode 120 and the second gate electrode 220 are separately formed, electrical reliability of the semiconductor device may be improved.

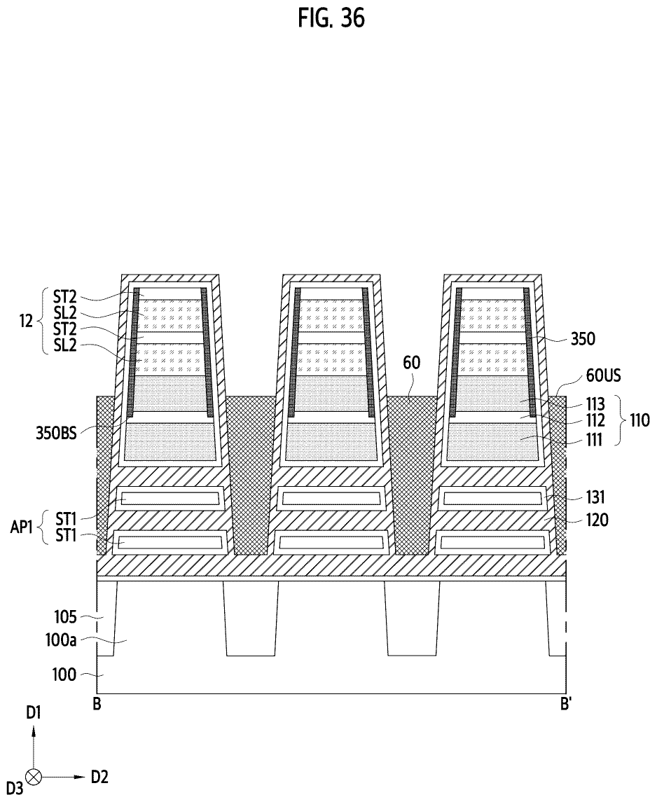

FIGS. 36 through 42 are diagrams illustrating an intermediate operation for describing a method for fabricating a semiconductor package illustrated in FIG. 7. FIG. 36 illustrates an operation after an operation illustrated in FIG. 24. In order to assist in understanding the present disclosure, a description will mainly focus on a point different from that described above with reference to FIGS. 11 through 35.

Referring to FIGS. 24 and 36, the blocking film 60 may be formed in the third trench TR3. The blocking film 60 may be formed on the first gate electrode 120 in the third trench TR3. The upper surface 60US of the blocking film 60 may be disposed above a lower surface 350BS of the protective film 350. The blocking film 60 may overlap the protective film 350 along the second direction D2.

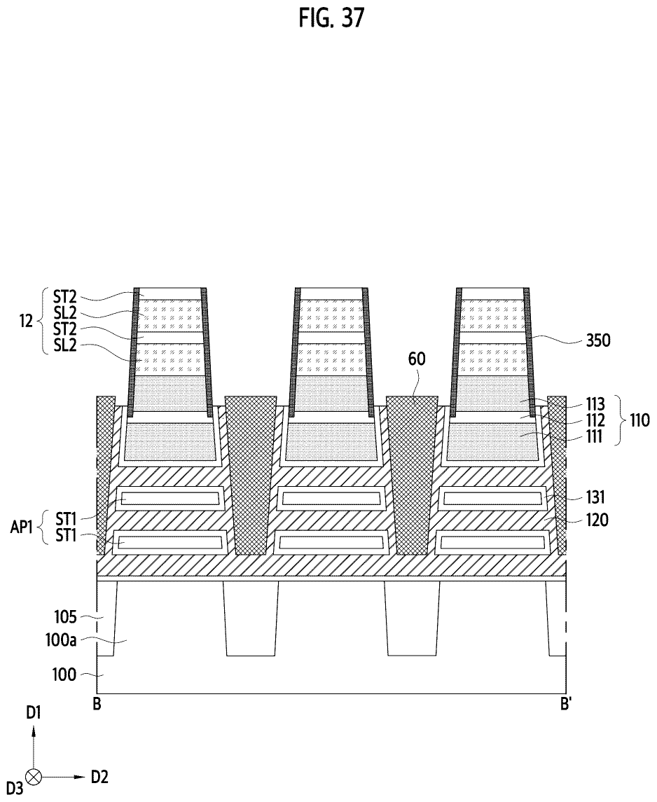

Referring to FIG. 37, other portions of the first gate insulation film 131 and the first gate electrode 120, which are not covered with the blocking film 60, may be removed. As the other portions of the first gate insulation film 131 and the first gate electrode 120, which are not covered with the blocking film 60, are removed, the protective film 350 and the second sheet ST2 may be exposed. Since the blocking film 60 covers the first gate insulation film 131 and the first gate electrode 120 from a position higher than the lower surface 350BS of the protective film 350, although the other portions of the first gate insulation film 131 and the first gate electrode 120 are removed, at least portions of the first gate insulation film 131 and the first gate electrode 120 may be positioned above the lower surface 350BS of the protective film 350. The protective film 350, the first gate electrode 131, and the second gate electrode 120 may overlap along the second direction D2. At least a portion of the protective film 350 may be covered with the first gate insulation film 131 and the first gate electrode 120.

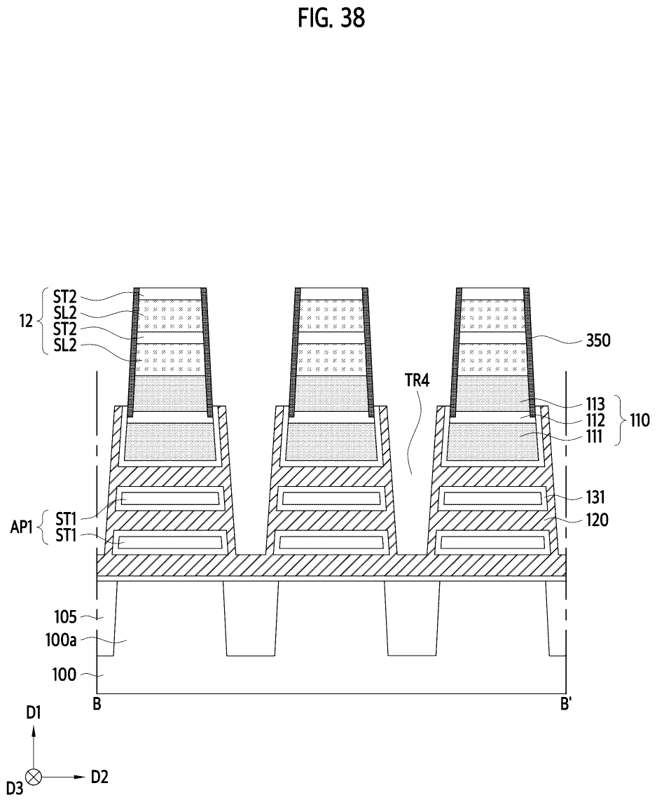

Referring to FIG. 38, the blocking film 60 may be removed. As the blocking film 60 is removed, the fourth trench TR4 may be formed on the first gate electrode 120.

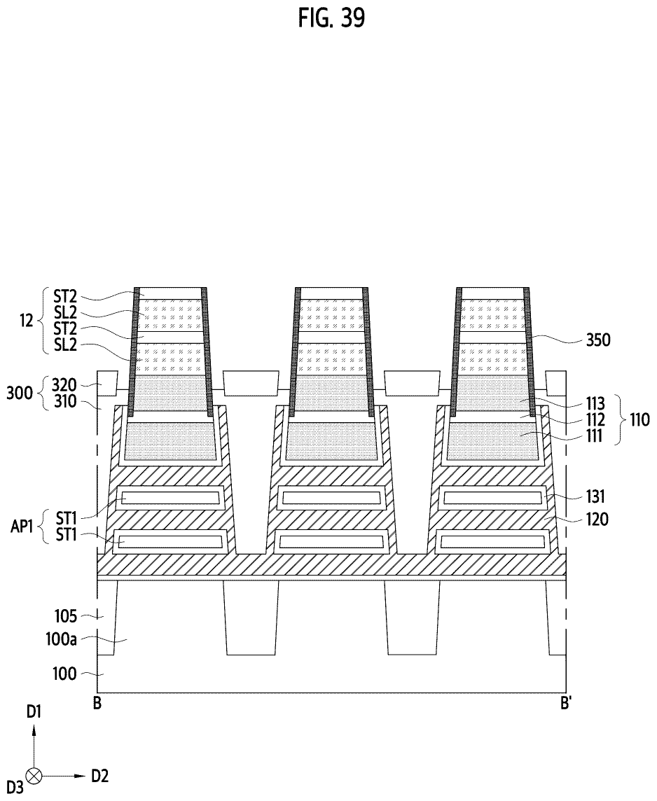

Referring to FIG. 39, the gate separation structure 300 may be formed. The gate separation structure 300 may fill the fourth trench TR4 (of FIG. 38). The first separator 310 may be formed along the first gate electrode 120, the first gate insulation film 131, and the protective film 350, and the second separator 320 may be formed on the first separator 310. The gate separation structure 300 may overlap the protective film 350 along the second direction D2. The gate separation structure 300 may not be in contact with the intermediate insulation structure 110. The gate separation structure 300 may be spaced apart from the intermediate insulation structure 110 with the protective film 350, the first gate insulation film 131, and the first gate electrode 120 in between.

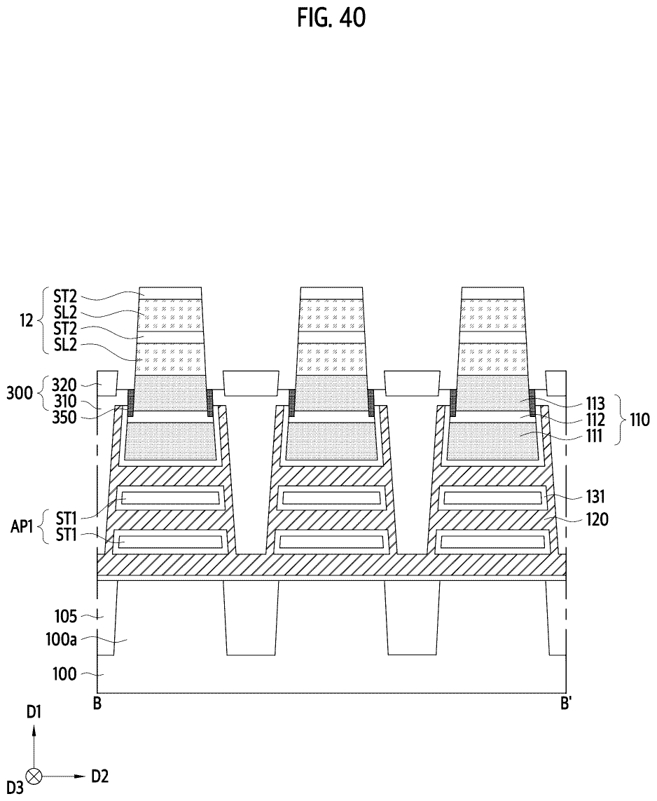

Referring to FIG. 40, at least a portion of the protective film 350 may be removed. A portion of the protective film 350, which is covered with the gate separation structure 300 and the first gate insulation film 131, may not be removed. A portion of the protective film 350, which is disposed on a step formed on a side surface of the intermediate insulation structure 110, may not be removed. The protective film 350, which is not removed as being covered with the gate separation structure 300 and the first gate insulation film 131, and an upper surface of the first separator 310 may be disposed on an identical plane. The protective film 350 may be removed, so that the second sacrificial layer SL2 and the second sheet ST2 of the second stack 12 may be exposed.

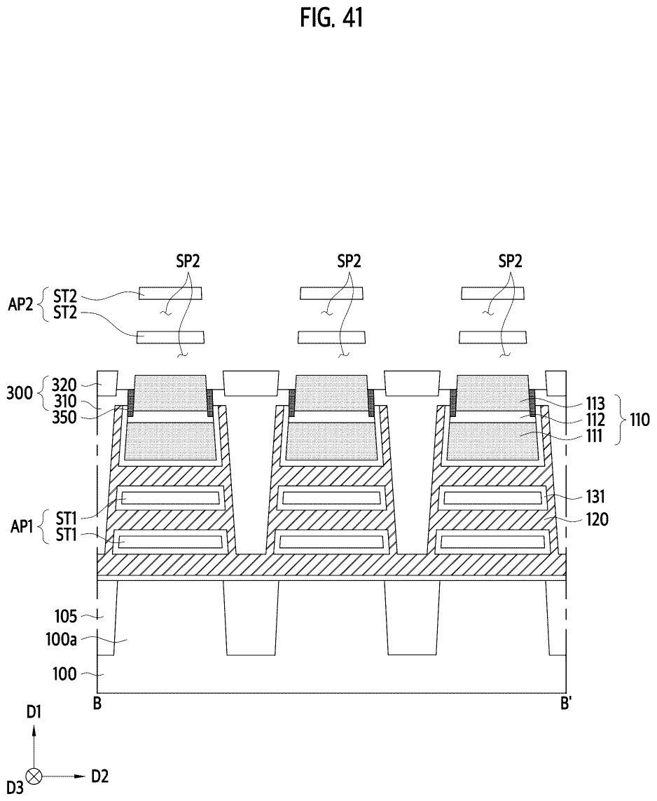

Referring to FIG. 41, the second sacrificial layer SL2 (of FIG. 40) may be removed. The second sacrificial layer SL2 (of FIG. 40) may be, for example, removed through a wet etching process. As the second sacrificial layer SL2 (of FIG. 40) is removed, the second space SP2 may be formed above and below the second active pattern AP2.

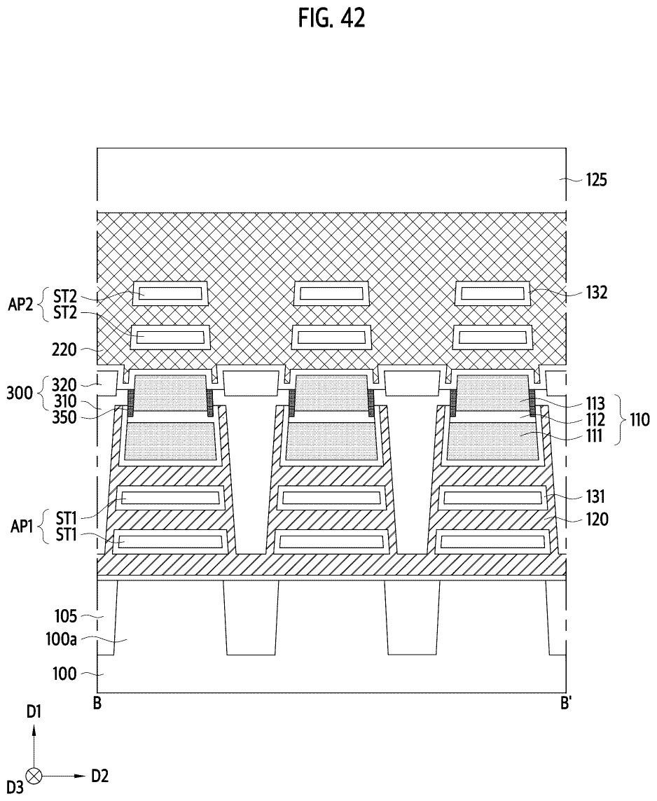

Referring to FIG. 42, the second gate insulation film 132 and the second gate electrode 220 may be formed. The second gate insulation film 132 and the second gate electrode 220 may surround the second active pattern AP2. The second gate insulation film 132 and the second gate electrode 220 may fill the second space SP2 (of FIG. 41). The protective film 350 may be surrounded by the second gate insulation film 132, the gate separation structure 300, the intermediate insulation structure 110, and the gate insulation film 131.

Then, referring to FIG. 7, the first gate contact 181 which is connected to the first gate electrode 120 and the second gate contact 182 which is connected to the second gate electrode 220 may be formed.

According to aspects, there is also provided a method of fabricating a semiconductor device, the method including forming a first stack including a first active layer and a first sacrificial layer that are alternately stacked above a substrate along a first direction crossing a surface of the substrate, a second stack including a second active layer and a second sacrificial layer that are alternately stacked along the first direction, and a third stack between the first stack and the second stack, patterning the second stack and an upper portion of the third stack so that the second stack is separated apart along a second direction crossing the first direction and so that the upper portion of the third stack is separated apart along the second direction, forming a protective film on a surface of the second stack and a surface of the upper portion of the third stack, patterning, by using the second stack, the upper portion of the third stack, and the protective film, the first stack and a lower portion of the third stack so that the first stack is separated apart along the second direction and so that the lower portion of the third stack is separated apart along the second direction, patterning the first stack the second stack and the third stack so that the first stack is separated apart along a third direction crossing the first direction and the second direction and so that the second stack is separated apart along the third direction, forming a first source/drain pattern connected to a first active pattern formed as the first active layer is patterned, forming a second source/drain pattern connected to a second active pattern formed as the second active layer is patterned, removing the first sacrificial layer, forming a first gate electrode configured to surround the first active pattern, forming a gate separation structure above the first gate electrode, removing the protective film, removing the second sacrificial layer, and forming a second gate electrode configured to surround the second active pattern above the first gate electrode and the gate separation structure.

The various example embodiments of the present disclosure have been described above in detail, but the scope of the present disclosure is not limited thereto. It will be apparent to those skilled in the art that various changes and modifications may be allowed within the range of the technical spirit of the present disclosure. In addition, the above-described example embodiments may be implemented without a portion of elements thereof, and each of the example embodiments may be implemented in combination with another.

What is claimed is:

1. A semiconductor device comprising:
a first active pattern disposed above a substrate and comprising a plurality of first sheets disposed to be spaced apart from one another along a first direction crossing a surface of the substrate;
a second active pattern disposed above the first active pattern and comprising a plurality of second sheets disposed to be spaced apart from one another along the first direction;
a first gate electrode configured to surround the first active pattern and extended along a second direction crossing the first direction;
a second gate electrode disposed above the first gate electrode, configured to surround the second active pattern, and extended along the second direction; and
an intermediate insulation structure overlapping the first active pattern and the second active pattern along the first direction and disposed between the first gate electrode and the second gate electrode in the first direction,
wherein a step is formed on a side surface of the intermediate insulation structure in the second direction.

2. The semiconductor device of claim 1, wherein the intermediate insulation structure comprises:
a first portion disposed above the first gate electrode; and
a second portion disposed on the first portion,
wherein a width of the first portion along the second direction is larger than a width of the second portion along the second direction.

3. The semiconductor device of claim 2, wherein a side surface of the first portion in the second direction is aligned with a side surface of the first active pattern, and
a side surface of the second portion in the second direction is aligned with a side surface of the second active pattern.

4. The semiconductor device of claim 2, further comprising a protective film disposed on the first portion and configured to cover at least a portion of a side surface of the second portion in the second direction.

5. The semiconductor device of claim 2, further comprising:
a first gate insulation film disposed between the first gate electrode and the first active pattern and configured to cover a lower surface of the first portion; and
a second gate insulation film disposed between the second gate electrode and the second active pattern and configured to cover an upper surface of the second portion.

6. The semiconductor device of claim 1, further comprising a gate separation structure disposed between the first gate electrode and the second gate electrode in the first direction and disposed at a side of the intermediate insulation structure in the second direction.

7. The semiconductor device of claim 6, wherein the gate separation structure comprises:
a first separator; and
a second separator on the first separator.

8. The semiconductor device of claim 7, wherein at least a portion of the first separator is inserted into the first gate electrode along the first direction.

9. The semiconductor device of claim 7, wherein the second gate electrode is configured to surround at least a portion of the second separator, which protrudes above an upper surface of the first separator.

10. The semiconductor device of claim 6, wherein the gate separation structure overlaps at least a portion of the first active pattern along the second direction.

11. A semiconductor device comprising:
a plurality of first active patterns disposed above a substrate, comprising a plurality of first sheets disposed to be spaced apart along a first direction crossing a surface of the substrate, and disposed to be spaced apart from one another along a second direction crossing the first direction;
a plurality of second active patterns disposed above the plurality of first active patterns, comprising a plurality of second sheets disposed to be spaced apart along the first direction, and disposed to be spaced apart from each other along the second direction;
a first gate electrode configured to surround the plurality of first active patterns and extended along the second direction;
a second gate electrode disposed above the first gate electrode, configured to surround the plurality of second active patterns, and extended along the second direction;
a gate separation structure disposed between the first gate electrode and the second gate electrode in the first direction and disposed between the plurality of first active patterns in the second direction; and
an intermediate insulation structure disposed between an uppermost first sheet among the plurality of first sheets and a lowermost second sheet among the plurality of second sheets and disposed at a side of the gate separation structure in the second direction,
wherein the intermediate insulation structure comprises a first portion and a second portion that are connected to one another along the first direction, and
a side surface of the first portion in the second direction is disposed, outwardly further than a side surface of the second portion in the second direction, toward the gate separation structure.

12. The semiconductor device of claim 11, wherein the intermediate insulation structure comprises multilayered films stacked along the first direction.

13. The semiconductor device of claim 11, wherein at least a portion of the side surface of the first portion in the second direction is in contact with the gate separation structure.

14. The semiconductor device of claim 11, wherein the gate separation structure comprises:
a first separator of which at least a portion is surrounded by the first gate electrode; and
a second separator that is disposed on the first separator along the first direction and of which at least a portion is surrounded by the first separator.

15. The semiconductor device of claim 14, wherein the first separator and the second separator comprise different materials.

16. The semiconductor device of claim 14, wherein at least a portion of the second gate electrode is inserted into a groove portion formed between the second separator and the intermediate insulation structure above the first separator.

17. The semiconductor device of claim 11, wherein a lower surface of the gate separation structure is disposed to be lower than a lower surface of a lowermost first sheet among the plurality of first sheets.

18. The semiconductor device of claim 11, wherein the side surface of the first portion in the second direction and side surfaces of the plurality of first sheets are disposed on an identical plane, and
the side surface of the second portion in the second direction and side surfaces of the plurality of second sheets are disposed on an identical plane.

19. The semiconductor device of claim 11, further comprising:
a first gate insulation film configured to surround the first gate electrode; and
a second gate insulation film configured to surround the second gate electrode,
wherein the second gate insulation film is extended along surficial profiles of the intermediate insulation structure and the gate separation structure.

20. A semiconductor device comprising:
a first active pattern disposed above a substrate and comprising a plurality of first sheets disposed to be spaced apart from one another along a first direction crossing a surface of the substrate;
a second active pattern disposed above the first active pattern and comprising a plurality of second sheets disposed to be spaced apart from one another along the first direction;
a first gate electrode configured to surround the first active pattern and extended along a second direction crossing the first direction;
a second gate electrode disposed above the first gate electrode, configured to surround the second active pattern, and extended along the second direction;
a first source/drain pattern disposed at a side of the first gate electrode in a third direction crossing the first direction and the second direction and connected to the first active pattern;
a second source/drain pattern disposed at a side of the second gate electrode in the third direction and connected to the second active pattern;
a first inter-layer insulation film disposed between the first source/drain pattern and the second source/drain pattern in the first direction;
an intermediate insulation structure disposed between the first gate electrode and the second gate electrode in the first direction and disposed at a side of the first inter-layer insulation film in the third direction; and
a gate separation structure disposed between the first gate electrode and the second gate electrode in the first direction, disposed at a side of the intermediate insulation structure in the second direction, and overlapping at least a portion of the first active pattern along the second direction,
wherein the intermediate insulation structure comprises:
a first portion disposed above the first gate electrode; and
a second portion disposed on the first portion and of which a width along the second direction is smaller than that of the first portion along the second direction, and
the gate separation structure is in contact with at least a portion of a side surface of the intermediate insulation structure.
